(19) United States
(12) Patent Application Publication
(10) Pub. No.: US 2025/0287593 A1
(43) Pub. Date: Sep. 11, 2025

(54) SEMICONDUCTOR STORAGE DEVICE

(71) Applicant: Kioxia Corporation, Tokyo (JP)

(72) Inventors: Hiroshi SHINOHARA, Yokosuka (JP); Hideto TAKEKIDA, Yokohama (JP); Hiroyasu TANAKA, Yokohama (JP); Masaru KIDOH, Komae (JP)

(73) Assignee: Kioxia Corporation, Tokyo (JP)

(21) Appl. No.: 18/828,685

(22) Filed: Sep. 9, 2024

(30) Foreign Application Priority Data
Mar. 7, 2024 (JP) 2024-035372

(51) Int. Cl. H10B 43/27; H10B 41/27

(52) U.S. Cl. CPC H10B 43/27; H10B 41/27

(57) ABSTRACT

A semiconductor storage device according to one embodiment includes a multi-layered body, a plurality of columnar bodies, a plurality of bit lines, and a plurality of dividing portions.

### CROSS-REFERENCE TO RELATED APPLICATION

This application is based upon and claims the benefit of priority from Japanese Patent Application No. 2024-035372 filed on Mar. 7, 2024; the entire contents of which are incorporated herein by reference.

### FIELD

Embodiments of the present invention relate to a semiconductor storage device.

### BACKGROUND ART

A NAND type flash memory including memory cells disposed three-dimensionally therein is known.

### BRIEF DESCRIPTION OF THE DRAWINGS

FIG. 1 is a block diagram showing a part of a semiconductor storage device according to a first embodiment.

FIG. 2 is a diagram showing an equivalent circuit of a part of a memory cell array according to the first embodiment.

FIG. 3 is a cross-sectional view showing a part of the semiconductor storage device according to the first embodiment.

FIG. 4 is an enlarged cross-sectional view showing the region surrounded by line F4 of the semiconductor storage device shown in FIG. 3.

FIG. 5 is a cross-sectional view along line F5-F5 of the semiconductor storage device shown in FIG. 4.

FIG. 6 is a cross-sectional view along line F6-F6 of the semiconductor storage device shown in FIG. 3.

FIG. 7 is an enlarged cross-sectional view showing the region surrounded by line F7 of the semiconductor storage device shown in FIG. 6.

FIG. 8 is a cross-sectional view along line F8-F8 of the semiconductor storage device shown in FIG. 3.

FIG. 9 is an enlarged cross-sectional view showing the region surrounded by line F9 of the semiconductor storage device shown in FIG. 8.

FIG. 10 is an enlarged cross-sectional view showing the region surrounded by line F10 of the semiconductor storage device shown in FIG. 8.

FIG. 11 is an enlarged cross-sectional view showing the region surrounded by line F11 of the semiconductor storage device shown in FIG. 3.

FIG. 12 is a cross-sectional view showing a manufacturing method of the semiconductor storage device according to the first embodiment.

FIG. 13 is a cross-sectional view for explaining a manufacturing method around a bit line according to the first embodiment.

FIG. 14 is a cross-sectional view for explaining the manufacturing method around the bit line according to the first embodiment.

FIG. 15 is a cross-sectional view for explaining the manufacturing method around the bit line according to the first embodiment.

FIG. 16 is a view for explaining advantages of the semiconductor storage device according to the first embodiment.

FIG. 17 is a view for explaining advantages of the semiconductor storage device according to the first embodiment.

FIG. 18 is a cross-sectional view showing a part of a semiconductor storage device according to a first modified example of the first embodiment.

FIG. 19 is a cross-sectional view showing a part of a semiconductor storage device according to a second modified example of the first embodiment.

FIG. 20 is a cross-sectional view showing a part of a semiconductor storage device according to a second embodiment.

FIG. 21 is a cross-sectional view showing a part of the semiconductor storage device according to the second embodiment.

FIG. 22 is a view for explaining advantages of the semiconductor storage device according to the second embodiment.

FIG. 23 is a cross-sectional view showing a part of a semiconductor storage device according to a first modified example of the second embodiment.

FIG. 24 is a cross-sectional view showing a part of a semiconductor storage device according to a second modified example of the second embodiment.

### DETAILED DESCRIPTION

A semiconductor storage device according to one embodiment includes a multi-layered body, a plurality of columnar bodies, a plurality of bit lines, and a plurality of dividing portions. The multi-layered body includes a plurality of gate electrode layers and a plurality of insulating layers. The plurality of gate electrode layers and the plurality of insulating layers are alternately stacked one by one in a first direction. The plurality of columnar bodies extend in the first direction within the multi-layered body. The plurality of columnar bodies and the plurality of gate electrode layers form intersections. The intersections include transistors. The plurality of bit lines are on one side of the multi-layered body in the first direction. The plurality of bit lines are in a second direction intersecting the first direction. Each of the plurality of bit lines extends in a third direction intersecting the first direction and the second direction. The plurality of dividing portions are separately in the third direction. Each of the plurality of dividing portions extends in the first direction within the multi-layered body. The plurality of dividing portions divide one or more gate electrode layers including a lowermost layer among the plurality of gate electrode layers in the third direction when the one side is defined as a downward side. The plurality of dividing portions include a first dividing portion and a second dividing portion adjacent to each other among the plurality of dividing portions. In a region between the first dividing portion and the second dividing portion, the plurality of columnar bodies include three or more columnar bodies in a first row extending in the third direction, and the plurality of columnar bodies include two or more columnar bodies in a second row extending in the third direction and adjacent to the first row in the second direction. The three or more columnar bodies and the two or more columnar bodies are alternately in the third direction. The three or more columnar bodies and the two or more columnar bodies are electrically connected to different bit lines among the plurality of bit lines.

Hereinafter, a semiconductor storage device according to an embodiment will be described with reference to the drawings. In the following description, components having the same or similar functions are denoted by the same reference signs. Also, duplicate description of the components may be omitted. In the following description, when a reference sign is appended with a number or an alphabetical letter at the end for distinction, the number or the alphabetical letter at the end may be omitted when there is no need for distinguishing.

In the present application, terms are defined as follows. “Parallel”, “orthogonal”, or “the same” may include a case of “substantially parallel”, “substantially orthogonal”, or “substantially the same”. “Connection” is not limited to a case of being mechanically connected, and may also include a case of being electrically connected. That is, “connection” is not limited to a case in which a plurality of elements are directly connected, and may include a case in which a plurality of elements are connected with another element interposed therebetween. “Overlapping” is not limited to a case in which a plurality of elements are in contact with each other, and can also include a case in which a plurality of elements are separated (a case in which projection images of the plurality of elements overlap each other when viewed from a certain direction).

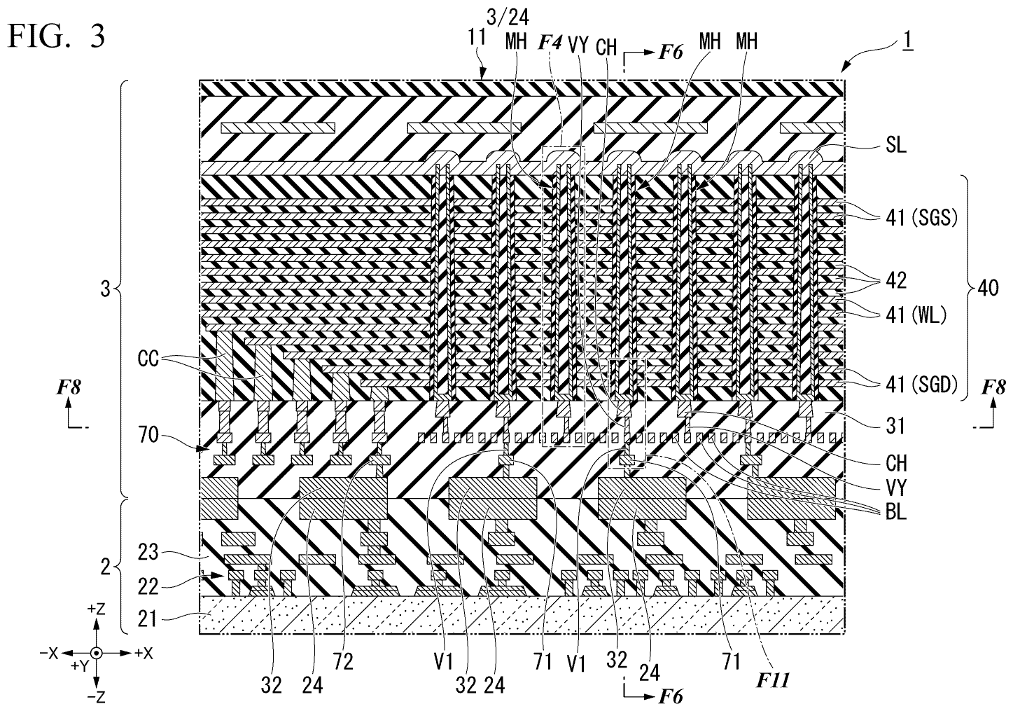

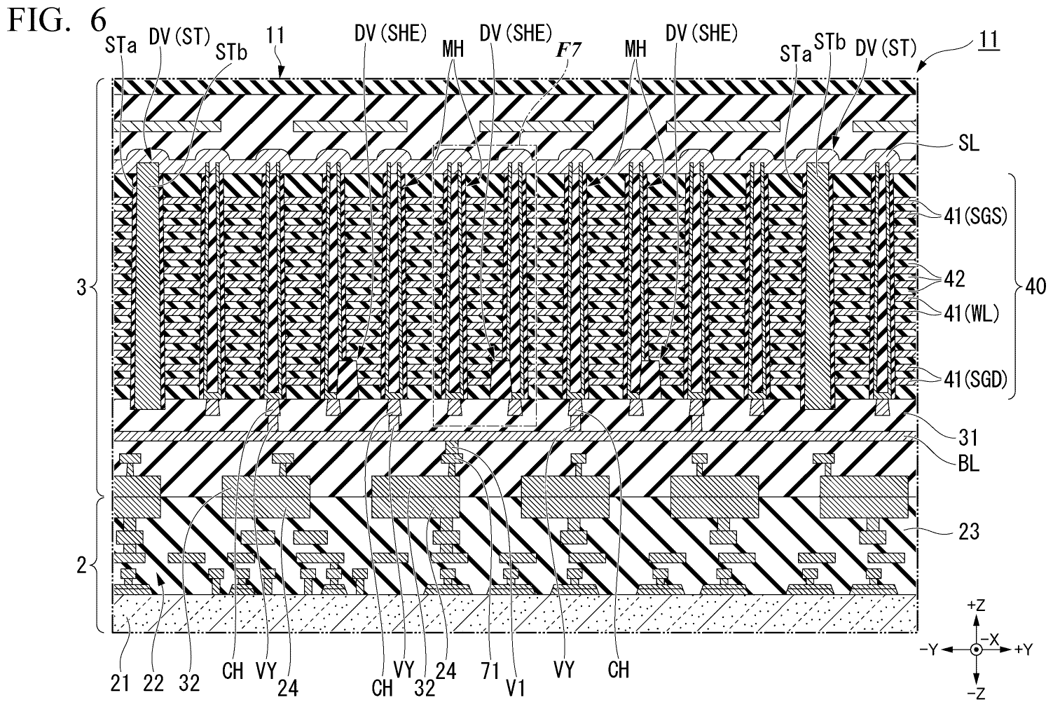

A +X direction, a −X direction, a +Y direction, a −Y direction, a +Z direction, and a −Z direction are defined as follows. The +X direction is a direction in which a word line WL to be described later extends (see FIG. 3). The −X direction is a direction opposite to the +X direction. In a case in which the +X direction and the −X direction do not need to be distinguished from each other, they will be simply referred to as an “X direction”. The +Y direction is a direction that intersects (for example, is orthogonal to) the X direction. The +Y direction is a direction in which a bit line BL extends (see FIG. 6). The −Y direction is a direction opposite to the +Y direction. In a case in which the +Y direction and the −Y direction do not need to be distinguished from each other, they will be simply referred to as a “Y direction”. The +Z direction is a direction that intersects (for example, is orthogonal to) the X direction and the Y direction. The +Z direction is a direction toward a multi-layered body 40 from the bit line BL to be described later (see FIG. 3). The −Z direction is a direction opposite to the +Z direction. In a case in which the +Z direction and the −Z direction do not need to be distinguished from each other, they will be simply referred to as a “Z direction”.

In the present application, the side in the +Z direction may be referred to using “upper” and the side in the −Z direction may be referred to using “lower”. However, these expressions are used for convenience of explanation and do not define a direction of gravity. The Z direction is an example of a “first direction”. The X direction is an example of a “second direction”. The Y direction is an example of a “third direction”. Also, in the drawings described below, illustration of components not related to the description may be omitted.

### First Embodiment

### A1. Configuration of Semiconductor Storage Device

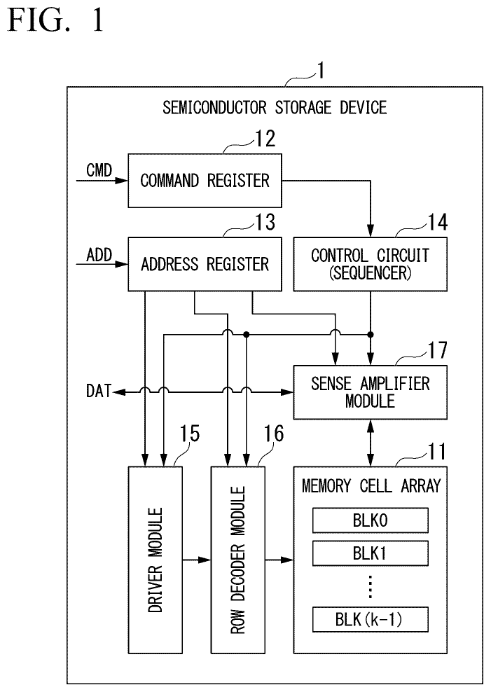

FIG. 1 is a block diagram showing a part of a semiconductor storage device 1. The semiconductor storage device 1 is, for example, a nonvolatile semiconductor storage device and is a NAND type flash memory. The semiconductor storage device 1 can be connected to an external host device and is used as a storage space for the host device. The semiconductor storage device 1 includes, for example, a memory cell array 11, a command register 12, an address register 13, a control circuit (sequencer) 14, a driver module 15, a row decoder module 16, and a sense amplifier module 17.

The memory cell array 11 includes a plurality of blocks BLK0 to BLK (k−1) (k is an integer of 1 or more). The block BLK is a set of memory cell transistors. The block BLK is used as a data erasing unit. A plurality of bit lines and a plurality of word lines are provided in the memory cell array 11. Each of the memory cell transistors is associated with one bit line and one word line.

The command register 12 holds a command CMD received by the semiconductor storage device 1 from the host device. The address register 13 holds address information ADD received by the semiconductor storage device 1 from the host device. The address information ADD is used to select a block BLK, a word line, and a bit line. The control circuit 14 controls various operations of the semiconductor storage device 1. For example, the control circuit 14 executes a write operation, a read operation, an erase operation, or the like of data based on the command CMD held in the command register 12.

The driver module 15 includes a voltage generation circuit, and generates voltages used in various operations of the semiconductor storage device 1. The row decoder module 16 transfers a voltage applied to a signal line corresponding to a selected word line to the selected word line. The sense amplifier module 17 applies a desired voltage to each bit line in the write operation. In the read operation, the sense amplifier module 17 determines a data value stored in each memory cell transistor based on a voltage of each bit line, and transfers the determination result to the host device as read data DAT.

### A2. Electrical Configuration of Memory Cell Array

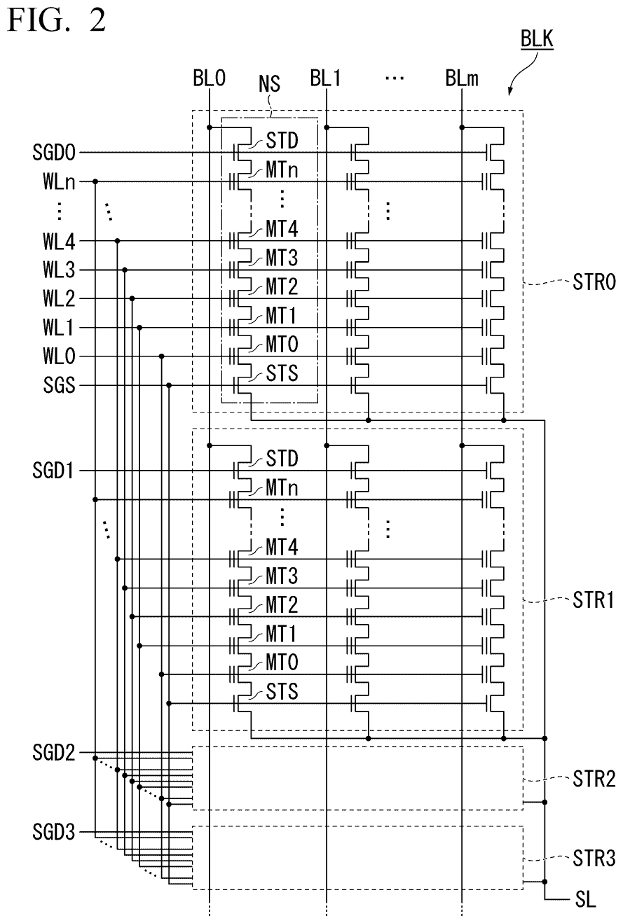

FIG. 2 is a diagram showing an equivalent circuit of a part of the memory cell array 11. FIG. 2 shows one block BLK included in the memory cell array 11. The block BLK includes a plurality of strings STR (for example, four strings STR0 to STR3).

Each string STR includes a plurality of NAND strings NS that are respectively associated with bit lines BL0 to BLm (m is an integer of 1 or more). Each NAND string NS includes, for example, a plurality of memory cell transistors MT0 to MTn (n is an integer of 1 or more), one or more drain-side selection transistors STD, and one or more source-side selection transistors STS.

In each NAND string NS, the memory cell transistors MT0 to MTn are connected in series. Each of the memory cell transistors MT includes a control gate and a charge storage portion. The control gate of the memory cell transistor MT is connected to any one of word lines WL0 to WLn. Each memory cell transistor MT stores charge in the charge storage portion according to a voltage applied to the control gate via the word line WL, and holds data non-volatilely.

A drain of the drain-side selection transistor STD is connected to the bit line BL corresponding to the NAND string NS. A source of the drain-side selection transistor STD is connected to one end of the memory cell transistors MT0 to MTn connected in series. A control gate of the drain-side selection transistor STD is connected to any one of the drain-side selection gate lines SGD0 to SGD3. The drain-side selection transistor STD is electrically connected to the row decoder module 16 via the drain-side selection gate line SGD. The drain-side selection transistor STD connects the NAND string NS and the bit line BL when a predetermined voltage is applied to the corresponding drain-side selection gate line SGD.

A drain of the source-side selection transistor STS is connected to the other end of the memory cell transistors MT0 to MTn connected in series. A source of the source-side selection transistor STS is connected to a source line SL. A control gate of the source-side selection transistor STS is connected to a source-side selection gate line SGS. The source-side selection transistor STS connects the NAND string NS and the source line SL when a predetermined voltage is applied to the source-side selection gate line SGS.

In the same block BLK, the control gates of the memory cell transistors MT0 to MTn are commonly connected to the corresponding word lines WL0 to WLn in one-to-one correspondence. In the same string STR, the control gates of the drain-side selection transistors STD are commonly connected to the corresponding drain-side selection gate lines SGD. The control gates of the source-side selection transistors STS are commonly connected to the source-side selection gate line SGS. In the memory cell array 11, the bit line BL is shared by the NAND strings NS to which the same column address is assigned in the plurality of strings STR.

In the present embodiment, a block size of the semiconductor storage device 1 is, for example, 100 MB or more. The “block size” refers to a capacity of the block BLK. Also, a page length of the semiconductor storage device 1 is, for example, 16 kB or more. The “page length” is a capacity defined by the number of the memory cell transistors MT corresponding to the same word line WL and the same drain-side selection gate line SGD.

### A3. Physical Configuration of Semiconductor Storage Device

Next, a physical configuration of the semiconductor storage device 1 will be described.

FIG. 3 is a cross-sectional view showing a part of the semiconductor storage device 1. The semiconductor storage device 1 includes, for example, a first chip 2 and a second chip 3.

### 3.1 First Chip

The first chip 2 is a circuit chip including peripheral circuits. The first chip 2 includes, for example, a semiconductor substrate 21, a peripheral circuit 22, an insulating portion 23, and a plurality of pads 24.

The semiconductor substrate 21 is, for example, a substrate that serves as a base of the first chip 2. At least a part of the semiconductor substrate 21 has a plate shape extending in the X direction and the Y direction. The semiconductor substrate 21 is formed of, for example, a semiconductor material such as silicon.

The peripheral circuit 22 is a circuit configured to realize the above-described function of the memory cell array 11. The peripheral circuit 22 includes one or more of the command register 12, the address register 13, the control circuit 14, the driver module 15, the row decoder module 16, and the sense amplifier module 17 described above. The insulating portion 23 covers the peripheral circuit 22. The plurality of pads 24 are provided on a surface of the insulating portion 23. Each of the pads 24 is electrically connected to the peripheral circuit 22.

### 3.2 Second Chip

The second chip 3 is an array chip that includes the memory cell array 11. The second chip 3 includes, for example, the memory cell array 11, an insulating portion 31, and a plurality of pads 32. Here, the insulating portion 31 and the plurality of pads 32 will be described, and the memory cell array 11 will be described later.

The insulating portion 31 covers the memory cell array 11. The plurality of pads 32 are provided on a surface of the insulating portion 31. Each of the pads 32 is electrically connected to a wiring (for example, a wiring 71 or a wiring 72) included in a wiring portion 70 of the memory cell array 11 to be described later. In the present embodiment, the first chip 2 and the second chip 3 are integrated by adhering the plurality of pads 24 of the first chip 2 and the plurality of pads 32 of the second chip 3 to face each other.

### A4. Physical Configuration of Memory Cell Array

Next, a physical configuration of the memory cell array 11 will be described.

As shown in FIG. 3, the memory cell array 11 has the multi-layered body 40, a source line SL, a plurality of memory pillars MH, a plurality of bit lines BL, a plurality of contacts CH for the memory pillars, a plurality of contacts VY for the memory pillars, a contact CC for a conductive layer, the wiring portion 70, and a plurality of dividing portions DV (see FIG. 6).

### 4.1 Multi-Layered Body

First, the multi-layered body 40 will be described.

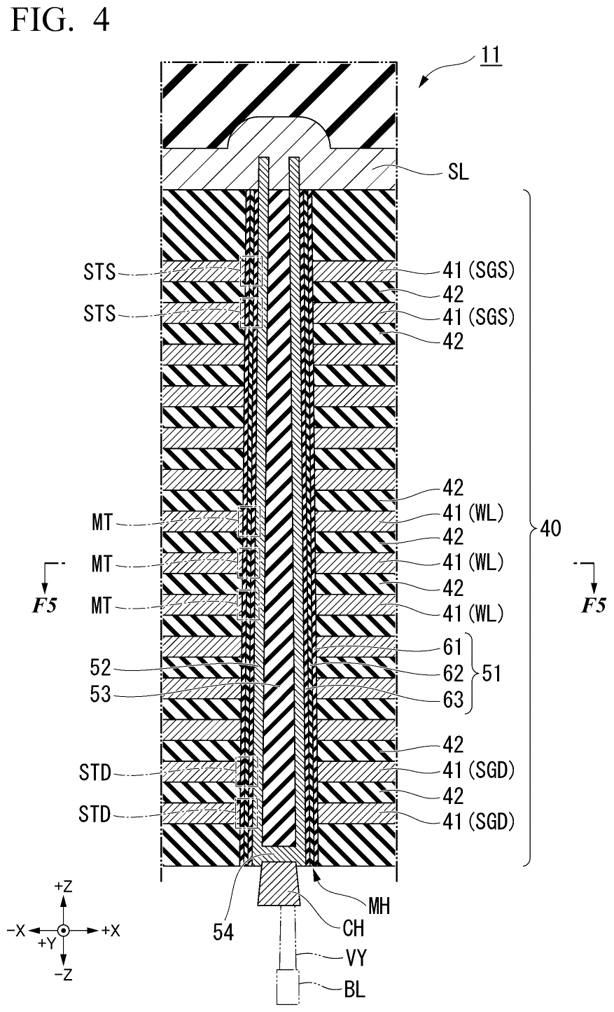

FIG. 4 is an enlarged cross-sectional view showing the region surrounded by line F4 of the semiconductor storage device 1 shown in FIG. 3. The multi-layered body 40 includes a plurality of conductive layers 41 and a plurality of insulating layers 42. The plurality of conductive layers 41 and the plurality of insulating layers 42 are alternately stacked one by one in the Z direction.

Each of the conductive layers 41 extends in the X direction and the Y direction. Each conductive layer 41 is formed of a conductive material such as, for example, tungsten or molybdenum. The conductive layer 41 is an example of a “gate electrode layer”.

One or more (for example, a plurality of) conductive layers 41 positioned on a lower side in the plurality of conductive layers 41 function as the drain-side selection gate line SGD. The drain-side selection gate line SGD is commonly provided for the plurality of memory pillars MH aligned in the X direction or the Y direction. A portion in which the drain-side selection gate line SGD and a channel layer 52 (to be described later) of each memory pillar MH intersect functions as the drain-side selection transistor STD described above.

One or more (for example, a plurality of) conductive layers 41 positioned on an upper side in the plurality of conductive layers 41 function as the source-side selection gate line SGS. The source-side selection gate line SGS is commonly provided for the plurality of memory pillars MH aligned in the X direction or the Y direction. A portion in which the source-side selection gate line SGS and the channel layer 52 of each memory pillar MH intersect functions as the source-side selection transistor STS described above.

Of the plurality of conductive layers 41, at least a part of the remaining conductive layers 41 provided between the conductive layers 41 functioning as the drain-side selection gate lines SGD and the source-side selection gate lines SGS function as the word line WL. The word line WL is commonly provided for the plurality of memory pillars MH aligned in the X direction and the Y direction. In the present embodiment, a portion in which the word line WL and the channel layer 52 of each memory pillar MH intersect functions as the memory cell transistor MT. The memory cell transistor MT will be described in detail later.

The insulating layer 42 is provided between two conductive layers 41 adjacent to each other in the Z direction. The insulating layer 42 is an interlayer insulating film that insulates the two conductive layers 41 from each other. The insulating layer 42 extends in the X direction and the Y direction. The insulating layer 42 is formed of, for example, a film containing silicon and oxygen.

### 4.2 Source Line

The source line SL is disposed above the multi-layered body 40. The source line SL is a conductive layer extending in the X direction and the Y direction. The source line SL is formed of a conductive material such as polysilicon or tungsten.

### 4.3 Memory Pillar

The plurality of memory pillars MH are aligned in the X direction and the Y direction (see FIG. 3). Each of the memory pillars MH extends in the Z direction within the multi-layered body 40. Each memory pillar MH penetrates the multi-layered body 40. An upper end of the memory pillar MH is in contact with the source line SL. On the other hand, a lower end of each memory pillar MH is in contact with the contact CH to be described later. The memory pillar MH is an example of a “columnar body”.

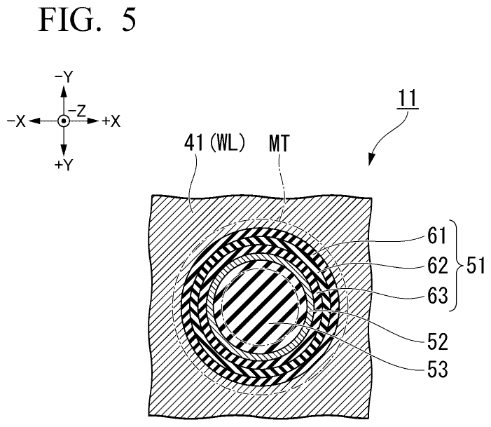

FIG. 5 is a cross-sectional view along line F5-F5 of the semiconductor storage device 1 shown in FIG. 4. The memory pillar MH includes, for example, a memory film (multilayer film) 51, the channel layer 52, an insulating core 53, and a cap portion 54 (see FIG. 4).

The memory film 51 is provided on an outer circumferential side of the channel layer 52. The memory film 51 is positioned between the plurality of conductive layers 41 and the channel layer 52. The memory film 51 includes, for example, a block insulating film 61, a charge trap film 62, and a tunnel insulating film 63.

The block insulating film 61 is provided between the plurality of conductive layers 41 and the charge trap film 62. The block insulating film 61 is an insulating film that suppresses back tunneling. Back tunneling is a phenomenon in which charge returns from the word line WL to the charge trap film 62. The block insulating film 61 is formed in an annular shape and extends in the Z direction. The block insulating film 61 is formed, for example, over the entire length of the memory pillar MH in the Z direction. The block insulating film 61 is a multi-layered structure film in which a plurality of insulating films such as, for example, a film containing silicon and oxygen or a film containing a metal and oxygen are stacked. An example of the film containing a metal and oxygen is aluminum oxide. The block insulating film 61 may contain a high dielectric constant material (high-k material) such as silicon nitride or hafnium oxide.

The charge trap film 62 is positioned between the block insulating film 61 and the tunnel insulating film 63. The charge trap film 62 is formed in an annular shape and extends in the Z direction. The charge trap film 62 is formed, for example, over the entire length of the memory pillar MH in the Z direction. The charge trap film 62 is a functional film that has a large number of crystal defects (trapping levels) and is capable of trapping charges in the crystal defects. The charge trap film 62 is formed of, for example, a film containing silicon and nitrogen. A portion of the charge trap film 62 adjacent to each word line WL is an example of a “charge storage portion” capable of storing information by storing charges.

The tunnel insulating film 63 is provided between the channel layer 52 and the charge trap film 62. The tunnel insulating film 63 has, for example, an annular shape along an outer circumferential surface of the channel layer 52. The tunnel insulating film 63 extends in the Z direction along the channel layer 52. The tunnel insulating film 63 is formed, for example, over the entire length of the memory pillar MH in the Z direction. The tunnel insulating film 63 is a potential barrier between the channel layer 52 and the charge trap film 62. The tunnel insulating film 63 is formed of a film containing silicon and oxygen, or a film containing silicon, oxygen, and nitrogen.

The channel layer 52 is provided inside the memory film 51. The channel layer 52 is formed in an annular shape. The channel layer 52 extends in the Z direction. The channel layer 52 is formed, for example, over the entire length of the memory pillar MH in the Z direction. The channel layer 52 is formed of a semiconductor material such as polysilicon. The channel layer 52 may be doped with impurities. When a voltage is applied to the word line WL, the channel layer 52 electrically connects the bit line BL and the source line SL by forming a channel.

Therefore, a metal-Al-nitride-oxide-silicon (MANOS) type memory cell transistor MT is formed at the same height as each word line WL by an end part of the word line WL adjacent to the memory pillar MH, the block insulating film 61, the charge trap film 62, the tunnel insulating film 63, and the channel layer 52. Note that, the memory film 51 may have a floating gate type charge storage portion (floating gate electrode) as the charge storage portion instead of the charge trap film 62. The floating gate electrode is formed of, for example, polysilicon containing impurities.

The insulating core 53 is provided inside the channel layer 52. The insulating core 53 fills at least a part of the inside of the channel layer 52. The insulating core 53 is formed of a film containing silicon and oxygen. A part of the insulating core 53 is formed in an annular shape along an inner circumferential surface of the channel layer 52. A part of the insulating core 53 may have a hollow portion (air gap) therein. The insulating core 53 extends in the Z direction. The insulating core 53 extends over most of the memory pillar MH in the Z direction excluding, for example, an upper end part of the memory pillar MH (see FIG. 4).

Next, returning to FIG. 4, the cap portion 54 will be described. The cap portion 54 is provided beneath the insulating core 53. The cap portion 54 is a semiconductor portion formed of a semiconductor material such as amorphous silicon or polysilicon. The cap portion 54 may be doped with impurities. The cap portion 54 is disposed on an inner circumferential side of a lower end part of the memory film 51. The cap portion 54 is formed integrally with the channel layer 52. The cap portion 54, together with a lower end part of the channel layer 52, forms a lower end part of the memory pillar MH. The contact CH is in contact with the cap portion 54 in the −Z direction.

### 4.4 Bit Line

Next, returning to FIG. 3, the bit line BL will be described. The bit line BL is a wiring for selecting one memory pillar MH from among the plurality of memory pillars MH. The plurality of bit lines BL are disposed on a lower side (in the side in the −Z direction) with respect to the multi-layered body 40. The plurality of bit lines BL are aligned in the X direction at intervals in the X direction. Each of the bit lines BL extends in the Y direction. Each bit line BL extends to pass beneath the plurality of corresponding memory pillars MH. The lower side with respect to the multi-layered body 40 is an example of “one side in the first direction with respect to the multi-layered body”.

When viewed from the Z direction, each bit line BL overlaps the plurality of memory pillars MH (see FIG. 6). Each bit line BL is connected to the channel layer 52 of the memory pillar MH via the contact VY and the contact CH to be described later. Therefore, the memory cell transistor MT can be optionally-selected from among the plurality of memory cell transistors MT disposed three-dimensionally by a combination of the word line WL and the bit line BL.

### 4.5 Contact CH for Memory Pillar

The plurality of contacts CH are disposed between the plurality of memory pillars MH and the plurality of bit lines BL. Each of the contacts CH is an electrical connection portion that electrically connects the contact VY and the memory pillar MH. The contact CH has, for example, a columnar shape or a truncated cone shape. When viewed from the Z direction, an outer shape of the contact CH is the same as, for example, an outer shape of the memory pillar MH, or is slightly smaller than the outer shape of the memory pillar MH.

The contact CH is disposed beneath the corresponding memory pillar MH. The contact CH is in contact with a lower end of the memory pillar MH. The contact CH is in contact with, for example, the cap portion 54 of the memory pillar MH (see FIG. 4). A connection area between the contact CH and the memory pillar MH (an overlapping area when viewed from the Z direction) is larger than a connection area between the contact VY and the contact CH to be described later. The contact CH is formed of a metal material such as, for example, tungsten or molybdenum. Even if the material of the contact CH and the material of the memory pillar MH are different, a satisfactory electrical connectivity between the contact CH and the memory pillar MH can be secured by increasing the connection area between the contact CH and the memory pillar MH to a certain extent.

### 4.6 Contact VY for Memory Pillar

The plurality of contacts VY are disposed between the plurality of contacts CH and the plurality of bit lines BL. Each of the contacts VY is an electrical connection portion that electrically connects the bit line BL and the contact CH. A width of the contact VY in the X direction is smaller than a width of the contact CH in the X direction.

The contact VY is disposed above the corresponding bit line BL. The contact VY is in contact with a lower end of the contact CH and the bit line BL. The contact VY is disposed at a position displaced from a center of the contact CH and a center of the memory pillar MH in the X direction. The contact VY is formed of a metal material such as, for example, tungsten or molybdenum. A material forming the contact VY is the same as, for example, the material forming the contact CH. Even if the connection area between the contact VY and the contact CH is small, a satisfactory electrical connectivity between the contact CH and the contact VY is secured when a material of the contact VY and a material of the contact CH are the same or similar.

### 4.7 Contact for Conductive Layer in Staircase Region

As shown in FIG. 3, the contact CC is an electrical connection portion that electrically connects the conductive layer 41 and the wiring 72 (to be described later) included in the wiring portion 70. The plurality of contacts CC are disposed in correspondence with, for example, a staircase region of the multi-layered body 40 in which end parts of the plurality of conductive layers 41 are disposed in a staircase shape. The plurality of contacts CC extend in the Z direction and have, for example, different lengths in the Z direction. An upper end of each contact CC is in contact with the corresponding conductive layer 41. The upper end of each contact CC is electrically connected to the corresponding conductive layer 41.

### 4.8 Wiring Portion

Next, the wiring portion 70 will be described. The wiring portion 70 is disposed between, for example, the multi-layered body 40 and the semiconductor substrate 21. The wiring portion 70 includes, for example, a plurality of wirings 71, a plurality of vias V1, and a plurality of wirings 72.

Each of the wirings 71 is an electrical connection portion that electrically connects the bit line BL and the pad 32. The plurality of wirings 71 are disposed, for example, below the plurality of bit lines BL. Each of the wirings 71 extends, for example, in the X direction or the Y direction. The via V1 electrically connecting the wiring 71 and the bit line BL is provided between the wiring 71 and the bit line BL.

The wiring 72 is an electrical connection portion electrically connecting the contact CC for a conductive layer and the pad 32. The wiring 72 is electrically connected to the conductive layer 41 via the contact CC for a conductive layer. A voltage is applied to the wiring 72 to select the conductive layer 41 (the word line WL, the drain-side selection gate line SGD, or the source-side selection gate line SGS).

### A5. Dividing Portion of Multi-Layered Body

Next, the dividing portion DV will be described.

FIG. 6 is a cross-sectional view showing the semiconductor storage device 1 along line F6-F6 shown in FIG. 3. In the present embodiment, a plurality of dividing portions DV are provided in the multi-layered body 40. The plurality of dividing portions DV are disposed separately in the Y direction. Each of the plurality of dividing portions DV extends in the Z direction within the multi-layered body 40. Each of the plurality of dividing portions DV divides one or more conductive layers 41 including a lowermost layer among the plurality of conductive layers 41 in the Y direction. The plurality of dividing portions DV include, for example, a plurality of dividing portions ST and a plurality of dividing portions SHE.

### 5.1 Dividing Portion ST

The dividing portion ST is a wall portion that divides the multi-layered body 40 in the Y direction. The plurality of dividing portions ST are disposed separately in the Y direction. The dividing portion ST extends in the Z direction, penetrates the multi-layered body 40, and extends in the X direction. That is, the dividing portion ST is a wall portion extending in the Z direction and the X direction. The dividing portion ST divides each of all the conductive layers 41 included in the multi-layered body 40 in the Y direction. The dividing portion ST includes, for example, an insulating portion STa and a conductive portion STb.

The insulating portion STa extends in the Z direction and penetrates the multi-layered body 40. The insulating portion STa divides each of the plurality of conductive layers 41 included in the multi-layered body 40 in the Y direction. The insulating portion STa is formed of, for example, a film containing silicon and oxygen.

The conductive portion STb is provided inside the insulating portion STa. The conductive portion STb extends in the Z direction and penetrates the multi-layered body 40. An upper end of the conductive portion STb is in contact with the source line SL. The conductive portion STb is formed of a conductive material such as tungsten or molybdenum. The conductive portion STb may function as, for example, an electrical connection portion connecting the source line SL and a wiring in the memory cell array 11.

### 5.2 Dividing Portion SHE

The dividing portion SHE is shallower dividing portion in the Z direction compared to the dividing portion ST. The dividing portion SHE is a wall portion that divides a lower end part of the multi-layered body 40 in the Y direction. The plurality of dividing portions SHE are disposed separately in the Y direction. In the present embodiment, a plurality of (for example, three) dividing portions SHE are present between two dividing portions ST adjacent to each other in the Y direction. The dividing portion SHE is provided at a lower end part of the multi-layered body 40. The dividing portion SHE extends to a middle of the multi-layered body 40 in the Z direction, and also extends in the X direction. That is, the dividing portion SHE is a wall portion extending in the Z direction and the X direction.

The dividing portion SHE penetrates a part of the conductive layers 41 including a lowermost layer among the plurality of conductive layers 41, and divides the part of the conductive layers 41 in the Y direction. For example, the dividing portion SHE penetrates each of all the conductive layers 41 functioning as the drain-side selection gate line SGD. On the other hand, the dividing portion SHE does not reach the conductive layer 41 functioning as the word line WL. The dividing portion SHE divides only the conductive layer 41 functioning as the drain-side selection gate line SGD in the Y direction. The dividing portion SHE is formed of, for example, a film containing silicon and oxygen.

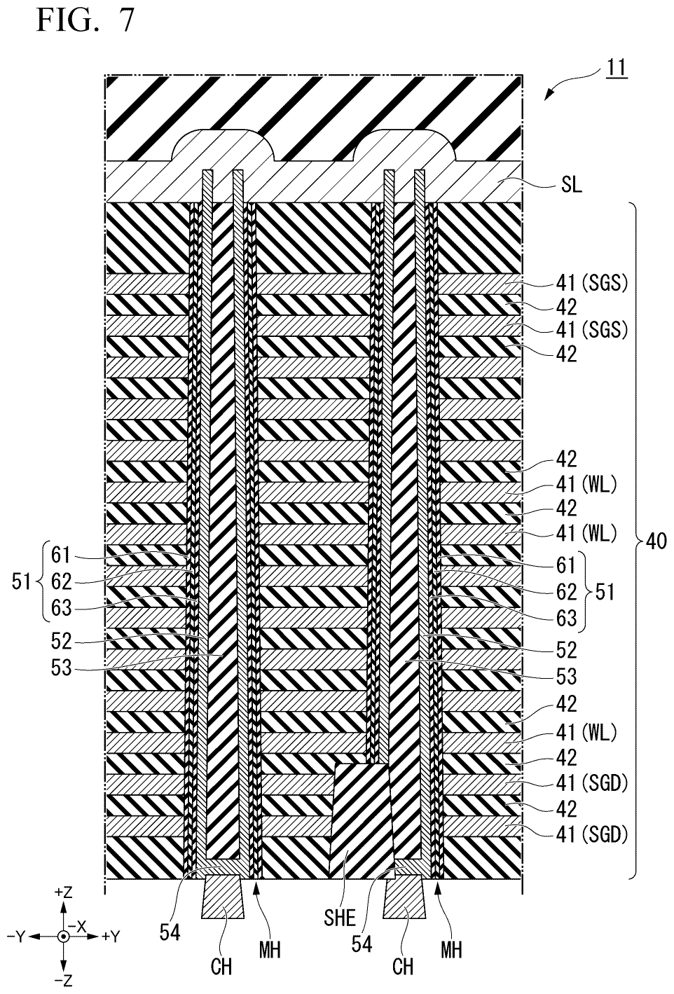

FIG. 7 is an enlarged cross-sectional view showing the region surrounded by line F7 of the semiconductor storage device 1 shown in FIG. 6. In the present embodiment, the dividing portion SHE is provided to bite into a part of the lower end part of the memory pillar MH. That is, when viewed from the Z direction, a part of the dividing portion SHE and a part of the memory pillar MH overlap each other. Therefore, as will be described in detail later, when viewed from the Z direction, the plurality of memory pillars MH are disposed at regular intervals regardless of the presence or absence of the dividing portion SHE.

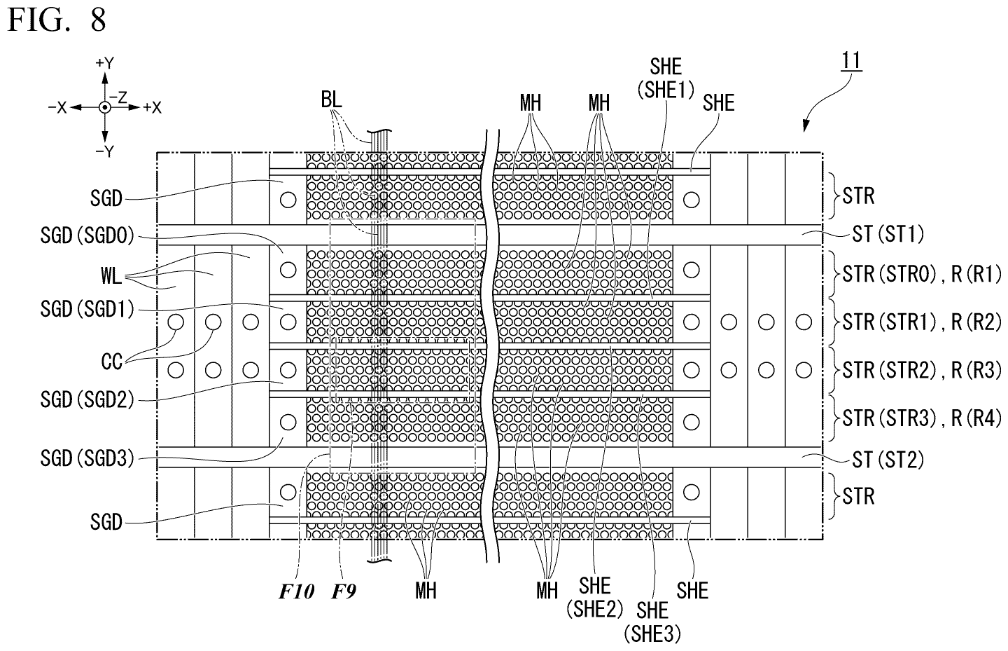

FIG. 8 is a cross-sectional view along line F8-F8 of the semiconductor storage device 1 shown in FIG. 3. In the present embodiment, the conductive layer 41 corresponding to the drain-side selection gate line SGD is divided in the Y direction by the dividing portion ST and the dividing portion SHE. Therefore, the drain-side selection gate line SGD extending in the X direction is formed. A region R divided by the dividing portion ST or the dividing portion SHE corresponds to one string STR.

In other words, the multi-layered body 40 has a plurality of regions R defined by the plurality of dividing portions ST and the plurality of dividing portions SHE. The plurality of regions R include, for example, a first region R1, a second region R2, a third region R3, and a fourth region R4. The first region R1, the second region R2, the third region R3, and the fourth region R4 are present between the two dividing portions ST adjacent to each other in the Y direction.

In the present embodiment, three dividing portions SHE (dividing portions SHE1, SHE2, and SHE3) are present between two dividing portions ST (dividing portions ST1 and ST2) adjacent to each other in the Y direction. The dividing portion SHE1, the dividing portion SHE2, and the dividing portion SHE3 are disposed in this order from the dividing portion ST1 to the dividing portion ST2. Therefore, the first region R1 is defined between the dividing portion ST1 and the dividing portion SHE1. The second region R2 is defined between the dividing portion SHE1 and the dividing portion SHE2. The third region R3 is defined between the dividing portion SHE2 and the dividing portion SHE3. The fourth region R4 is defined between the dividing portion SHE3 and the dividing portion ST2.

### A6. Connection Structure Between Memory Pillar and Bit Line

Next, a connection structure between the memory pillar MH and the bit line BL will be described.

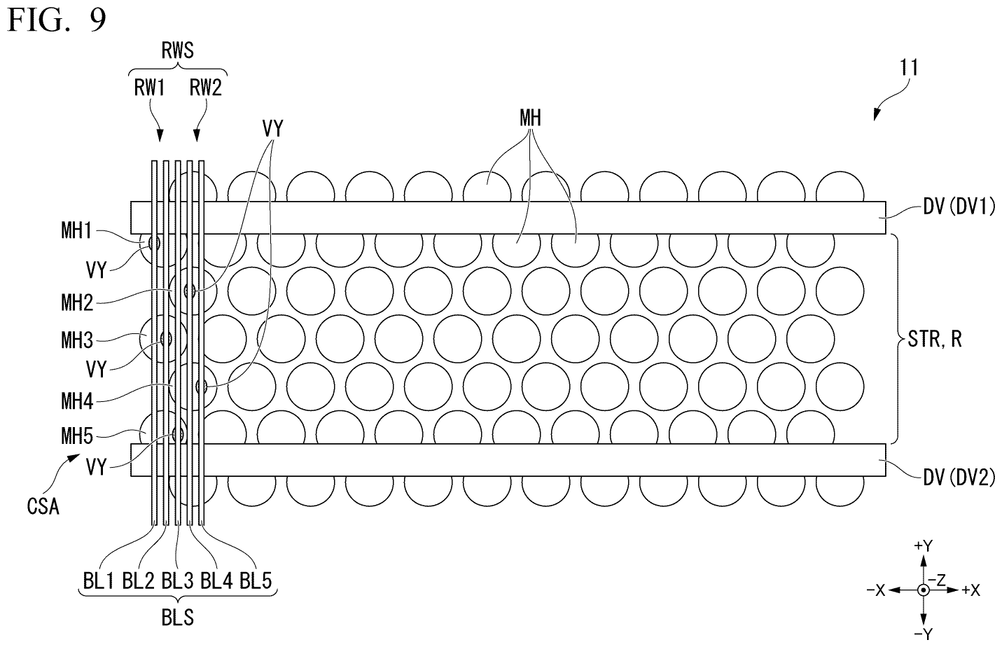

FIG. 9 is an enlarged cross-sectional view showing the region surrounded by line F9 of the semiconductor storage device 1 shown in FIG. 8. Note that, for convenience of explanation, illustration of the contact CH is omitted in FIG. 9. This also applies to some of the drawings described below.

FIG. 9 shows a structure related to two adjacent dividing portions DV (a first dividing portion DV1 and a second dividing portion DV2) among the plurality of dividing portions DV. In the example shown in FIG. 9, the first dividing portion DV1 and the second dividing portion DV2 are formed by the dividing portion SHE. Note that, one or both of the first dividing portion DV1 and the second dividing portion DV2 may be formed by the dividing portion ST instead of the dividing portion SHE. The region R corresponding to one string STR is defined between the first dividing portion DV1 and the second dividing portion DV2.

In the present embodiment, the plurality of memory pillars MH are disposed such that each of the memory pillars MH is positioned at corners and a center of a plurality of imaginary hexagons laid out in a hexagonal lattice pattern. In the present embodiment, the plurality of memory pillars MH are disposed in the region R between two adjacent dividing portions DV in a disposition structure in which five memory pillars MH are aligned in the Y direction (hereinafter, referred to as a “disposition structure of five in series”). Note that, in the present application, the phrase “the plurality of memory pillars being aligned in a specific direction” is not limited to the plurality of memory pillars MH being aligned in a straight line in the specific direction, but may also include the plurality of memory pillars MH being aligned in a staggered pattern in the specific direction. That is, the phrase “the plurality of memory pillars being aligned in the Y direction” means that positions of the plurality of memory pillars MH in the Y direction are different, and positions of the plurality of memory pillars MH in the X direction may be different from each other.

In the present embodiment, a connection structure between a bit line set BLS including five bit lines BL (bit lines BL1 to BL5) adjacent to each other in the X direction and five memory pillars MH (memory pillars MH1 to MH5) corresponding to the five bit lines BL forms one structural unit. Then, the above-described connection structure is repeatedly present in the X direction for every five bit lines BL. Also, the above-described connection structure is repeatedly present for each region R in the Y direction. Therefore, in the following, one connection structure will be described in detail.

### 6.1 Disposition of Memory Pillars

The above-described five memory pillars MH include a first memory pillar MH1, a second memory pillar MH2, a third memory pillar MH3, a fourth memory pillar MH4, and a fifth memory pillar MH5. The first memory pillar MH1, the second memory pillar MH2, the third memory pillar MH3, the fourth memory pillar MH4, and the fifth memory pillar MH5 are aligned in that order in the Y direction.

In the present embodiment, the first memory pillar MH1, the second memory pillar MH2, the third memory pillar MH3, the fourth memory pillar MH4, and the fifth memory pillar MH5 are disposed separately in a first row RW1 and a second row RW2 included in one row set RWS. The first row RW1 and the second row RW2 are two rows adjacent to each other in the X direction. The first row RW1 and the second row RW2 are two rows each of which extends in the Y direction. The first memory pillar MH1, the second memory pillar MH2, the third memory pillar MH3, the fourth memory pillar MH4, and the fifth memory pillar MH5 are alternately disposed in the first row RW1 and the second row RW2. For example, the first memory pillar MH1, the third memory pillar MH3, and the fifth memory pillar MH5 are disposed in the first row RW1. The second memory pillar MH2 and the fourth memory pillar MH4 are disposed in the second row RW2. In the present embodiment, the first memory pillar MH1, the second memory pillar MH2, the third memory pillar MH3, the fourth memory pillar MH4, and the fifth memory pillar MH5 partially overlap each other when viewed from the Y direction.

### 6.2 Disposition of Bit Lines

The above-described five bit lines BL include a first bit line BL1, a second bit line BL2, a third bit line BL3, a fourth bit line BL4, and a fifth bit line BL5. The first bit line BL1, the second bit line BL2, the third bit line BL3, the fourth bit line BL4, and the fifth bit line BL5 are disposed in that order in the X direction.

### 6.3 Connection Structure

The first memory pillar MH1 overlaps the first bit line BL1 when viewed from the Z direction. The first memory pillar MH1 is electrically connected to the first bit line BL1 via the contact VY. The second memory pillar MH2 overlaps the fourth bit line BL4 when viewed from the Z direction. The second memory pillar MH2 is electrically connected to the fourth bit line BL4 via the contact VY. The third memory pillar MH3 overlaps the second bit line BL2 when viewed from the Z direction. The third memory pillar MH3 is electrically connected to the second bit line BL2 via the contact VY. The fourth memory pillar MH4 overlaps the fifth bit line BL5 when viewed from the Z direction. The fourth memory pillar MH4 is electrically connected to the fifth bit line BL5 via the contact VY. The fifth memory pillar MH5 overlaps the third bit line BL3 when viewed from the Z direction. The fifth memory pillar MH5 is electrically connected to the third bit line BL3 via the contact VY.

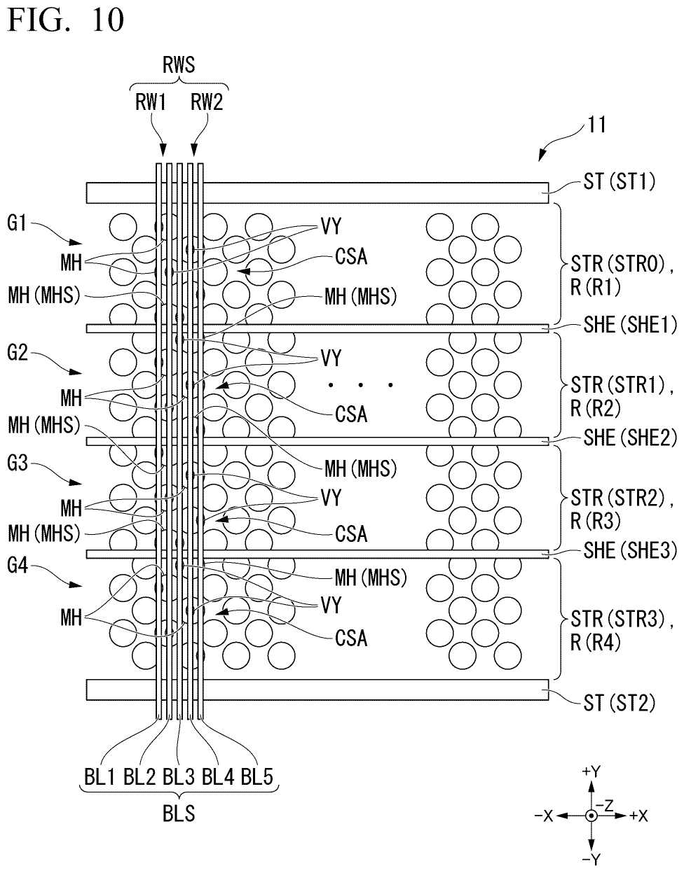

As described above, each of the five memory pillars MH (MH1 to MH5) is electrically connected to different bit lines BL within the five bit lines BL (BL1 to BL5) included in one bit line set BLS. In the following, the connection structure between the five memory pillars MH and the five bit lines BL described above will be referred to as a connection structure CSA. In the present embodiment, the connection structure CSA is provided in each of the four regions R (regions R1 to R4). Note that, the connection structure CSA provided in the first region R1 and the third region R3 and the connection structure CSA provided in the second region R2 and the fourth region R4 have a disposition that is, for example, line-symmetrical with respect to a virtual line extending in the Y direction, or rotationally symmetrical with respect to a virtual center provided at a position overlapping the dividing portion DV (see FIG. 10).

FIG. 10 is an enlarged cross-sectional view showing the region surrounded by line F10 of the semiconductor storage device 1 shown in FIG. 8. In the present embodiment, 20 memory pillars MH are aligned in the Y direction in a region between two adjacent dividing portions ST (dividing portions ST1 and ST2). The 20 memory pillars MH are disposed alternately in the first row RW1 and the second row RW2. The 20 memory pillars MH include five memory pillars MH in a first group G1, five memory pillars MH in a second group G2, five memory pillars MH in a third group G3, and five memory pillars MH in a fourth group G4.

The five memory pillars MH of the first group G1 are disposed in the first region R1. Each of the five memory pillars MH in the first group G1 is electrically connected to different bit lines BL within the five bit lines BL (BL1 to BL5). The five memory pillars MH of the second group G2 are disposed in the second region R2. Each of the five memory pillars MH in the second group G2 is electrically connected to different bit lines BL within the five bit lines BL (BL1 to BL5). The five memory pillars MH of the third group G3 are disposed in the third region R3. Each of the five memory pillars MH in the third group G3 is electrically connected to different bit lines BL within the five bit lines BL (BL1 to BL5). The five memory pillars MH of the fourth group G4 are disposed in the fourth region R4. Each of the five memory pillars MH in the fourth group G4 is electrically connected to different bit lines BL within the five bit lines BL (BL1 to BL5).

In the present embodiment, each of the first group G1 to the fourth group G4 includes a memory pillar MHS that is closest to the adjacent region R. As described above, a part of the memory pillar MHS overlaps the dividing portion SHE when viewed from the Z direction. In the present embodiment, the memory pillar MHS overlapping the dividing portion SHE when viewed from the Z direction is a memory pillar MH that is connected to the bit line BL via the contact VY to function electrically. That is, the memory cell transistor MT used for storing data is formed at a portion in which the memory pillar MHS and the word line WL intersect. In the present embodiment, when viewed from the Z direction, the plurality (for example, 20) of memory pillars MH disposed between two dividing portions ST and aligned in the Y direction are disposed at regular intervals regardless of whether or not they are memory pillars MHS. When viewed from the Z direction, the plurality of memory pillars MH are disposed at regular intervals regardless of the presence or absence of the dividing portion SHE.

As described above, in the region R between the first dividing portion DV1 and the second dividing portion DV2 disposed adjacent to the first dividing portion DV1 in the Y direction, the plurality of memory pillars MH include three or more memory pillars MH (for example, three memory pillars MH1, MH3, and MH5) disposed in the first row RW1 extending in the Y direction, and two or more memory pillars MH (for example, two memory pillars MH2 and MH4) disposed in the second row RW2 extending in the Y direction and adjacent to the first row RW1 in the X direction. The three or more memory pillars MH (for example, the three memory pillars MH1, MH3, and MH5) and the two or more memory pillars MH (for example, the two memory pillars MH2 and MH4) are disposed alternately in the Y direction. Then, the three or more memory pillars MH (for example, the three memory pillars MH1, MH3, and MH5) and the two or more memory pillars MH (for example, the two memory pillars MH2 and MH4) are electrically connected to different bit lines BL within the plurality of bit lines BL.

### A7. Structure Related to Bit Line

Next, a structure related to the bit line BL will be described. Here, a connection structure between the bit line BL2 and the memory pillar MH connected to the bit line BL2 will be taken up and described. The bit line BL2 is an example of a “first bit line”. The bit line BL3 is an example of a “second bit line”. The memory pillar MH connected to the bit line BL2 is an example of a “first columnar body”.

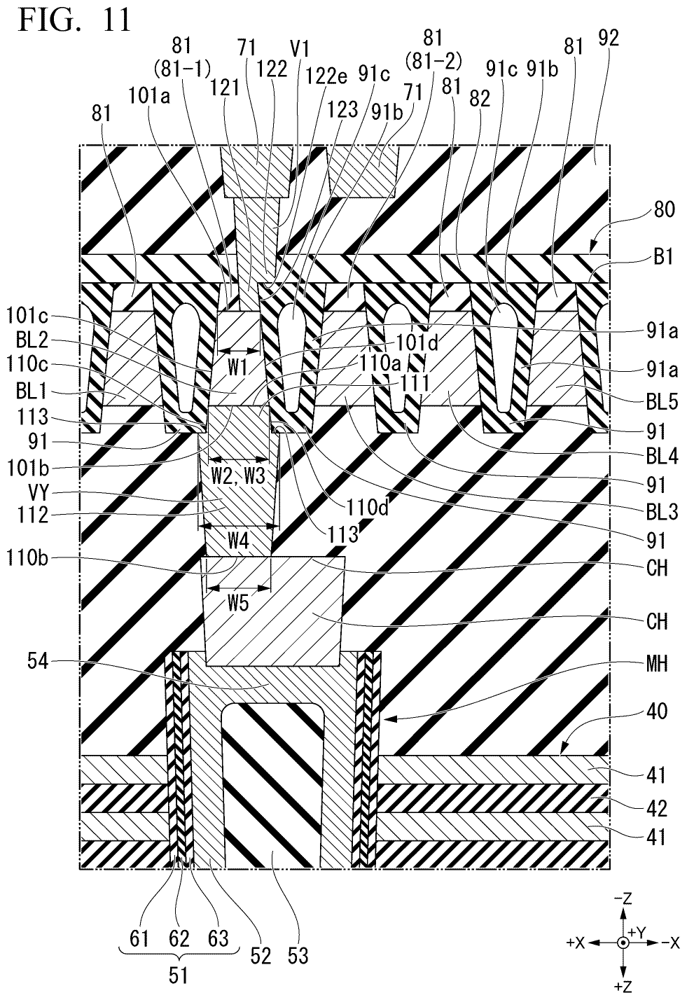

FIG. 11 is an enlarged cross-sectional view showing the region surrounded by line F11 of the semiconductor storage device 1 shown in FIG. 3. Note that, FIG. 11 is shown upside down with respect to FIG. 3. As shown in FIG. 11, the memory cell array 11 has the plurality of bit lines BL, the plurality of contacts VY (only one is shown in FIG. 11), an insulating layer 80, a plurality of first insulating portions 91, the plurality of vias V1 (only one is shown in FIG. 11), and a second insulating portion 92 described above.

### 7.1 Bit Line

First, a shape of the bit line BL will be described. The bit line BL is formed of, for example, a wiring material that can be processed by reactive ion etching (RIE). The bit line BL is formed of, for example, tungsten, molybdenum, chromium, or ruthenium.

In the present embodiment, each bit line BL has a first end 101a and a second end 101b in a cross section in the X direction and the Z direction. The first end 101a is an end on a side in which the wiring 71 and the via V1 are positioned in the Z direction. The first end 101a is an end that faces a side opposite to the multi-layered body 40. The first end 101a is in contact with a first layer portion 81 of the insulating layer 80, which will be described later, in the Z direction. On the other hand, the second end 101b is positioned on a side opposite to the first end 101a in the Z direction. The second end 101b is an end on a side in which the contact VY and the memory pillar MH are positioned. The second end 101b is an end facing the multi-layered body 40. The second end 101b is in contact with the contact VY in the Z direction.

In the present embodiment, the plurality of bit lines BL are patterned by reactive ion etching from a side opposite to the multi-layered body 40 (on the side in the −Z direction). Therefore, regarding each bit line BL, a width W1 in the X direction of the first end 101a of the bit line BL is smaller than a width W2 in the X direction of the second end 101b of the bit line BL. In a cross section in the X direction and the Z direction, each bit line BL has a trapezoidal shape in which a width in the X direction gradually increases as the bit line BL comes closer to the multi-layered body 40 (closer to the memory pillar MH).

In a cross section in the X direction and the Z direction, each bit line BL has a first side end 101c and a second side end 101d positioned on a side opposite to the first side end 101c in the X direction. The first side end 101c is formed across an edge on the side in the +X direction of the first end 101a and an edge on the side in the +X direction of the second end 101b. The first side end 101c is in contact with the first insulating portion 91, which will be described later, in the X direction. The second side end 101d is formed across an edge on the side in the −X direction of the first end 101a and an edge on the side in the −X direction of the second end 101b. The second side end 101d is in contact with the first insulating portion 91 at a position different from the first side end 101c.

### 7.2 Contact

Next, a shape of the contact VY will be described. The contact VY includes, for example, a first portion 111 and a second portion 112.

The first portion 111 of the contact VY is a portion that is in contact with the bit line BL. The first portion 111 has, for example, a first end 110a, a first side end 110c, and a second side end 110d.

The first end 110a is in contact with the second end 101b of the bit line BL in the Z direction. The first side end 110c extends from an edge of the first end 110a on the side in the +X direction toward a side opposite to the bit line BL. The second side end 110d extends from an edge of the first end 110a on the side in the −X direction toward a side opposite to the bit line BL.

In the present embodiment, the first portion 111 of the contact VY is patterned together with the bit line BL by reactive ion etching. Therefore, in a cross section in the X direction and the Z direction, the first portion 111 has a trapezoidal shape in which a width in the X direction gradually increases as the first portion 111 comes closer to the multi-layered body 40 (closer to the memory pillar MH). A width W3 in the X direction of the first end 110a is the same as the width W2 in the X direction of the second end 101b of the bit line BL. The width W3 of the first end 110a in the X direction is smaller than, for example, a maximum width W4 of the second portion 112 in the X direction.

The first side end 110c of the first portion 111 is processed integrally with the first side end 101c of the bit line BL by reactive ion etching. The first side end 110c extends to be continuous with the first side end 101c of the bit line BL. The second side end 110d of the first portion 111 is processed integrally with the second side end 101d of the bit line BL by reactive ion etching. The second side end 110d extends to be continuous with the second side end 101d of the bit line BL.

On the other hand, the second portion 112 of the contact VY is provided between the first portion 111 and the contact CH. The second portion 112 is in contact with the contact CH. In a cross section in the X direction and the Z direction, the second portion 112 has an inverted trapezoidal shape in which a width in the X direction gradually decreases as the second portion 112 comes closer to the multi-layered body 40 (closer to the memory pillar MH). A step 113 at which a width of the contact VY in the X direction increases is present between the second portion 112 and the first portion 111 of the contact VY. Also, the contact VY has a second end 110b that is in contact with the contact CH. A width W5 of the second end 110b in the X direction is larger than the width W3 of the first end 110a in the X direction.

### 7.3 Insulating Layer

Next, the insulating layer 80 will be described. The insulating layer 80 is an insulating layer that suppresses an influence of positional deviation, for example, when the via V1 is positionally deviated with respect to the bit line BL. The insulating layer 80 is disposed on a side opposite to the memory pillars MH with respect to the plurality of bit lines BL. The insulating layer 80 has, for example, a plurality of first layer portions 81 and a second layer portion 82. Note that, for convenience of explanation, the first layer portions 81 and the second layer portion 82 are hatched differently in FIG. 11. However, the first layer portion 81 and the second layer portion 82, for example, contain the same material and exist integrally. Therefore, a boundary between the first layer portions 81 and the second layer portion 82 disappears, and they exist as a single insulating layer 80.

### 7.3.1 First Layer Portion of Insulating Layer

The plurality of first layer portions 81 are provided separately in the X direction. The plurality of first layer portions 81 are provided to correspond to the plurality of bit lines BL, and overlap the plurality of bit lines BL when viewed from the Z direction. The first layer portion 81 is a portion of the insulating layer 80 that is responsible for, for example, electrical insulation (withstand voltage). The first layer portion 81 is positioned on the side in the −Z direction with respect to the corresponding bit line BL. The first layer portion 81 is stacked on the bit line BL. The first layer portion 81 extends in the Y direction along a surface of the bit line BL. The plurality of first layer portions 81 are disposed at intervals from each other in the X direction.

The first layer portion 81 includes, for example, an insulating material containing nitrogen. The insulating material is one of, for example, a film containing silicon and nitrogen (for example, SiN), a film containing silicon, carbon, and nitrogen (for example, SiCN), or a film containing silicon, oxygen, and nitrogen (for example, SiON). When an etching selectivity between the first insulating portion 91 and the first layer portion 81 to be described below is taken into consideration, silicon nitride (SiN) or silicon carbonitride (SiCN) is preferable as the insulating material.

In the present embodiment, the plurality of first layer portions 81 are patterned together with the bit lines BL by, for example, reactive ion etching. Therefore, in a cross section in the X direction and the Z direction, the first layer portion 81 has a trapezoidal shape in which a width in the X direction gradually increases as the first layer portion 81 comes closer to a side in which the multi-layered body 40 (memory pillar MH) is positioned. In the present embodiment, the first layer portion 81 (81-1) overlapping the bit line BL2 when viewed from the Z direction is an example of a “first portion of the insulating layer”. The first layer portion 81 (81-2) overlapping the bit line BL3 when viewed from the Z direction is an example of a “second portion of the insulating layer”.

### 7.3.2 Second Layer Portion of Insulating Layer

The second layer portion 82 is a portion that functions as, for example, a stopper layer with respect to processing of a hole for forming the via V1 when the hole is processed. The second layer portion 82 is positioned on the side in the −Z direction with respect to the plurality of first layer portions 81. That is, the second layer portion 82 is positioned on a side opposite to the plurality of bit lines BL with respect to the plurality of first layer portions 81. The second layer portion 82 extends at least in the X direction to span across the plurality of first layer portions 81. In the present embodiment, the second layer portion 82 extends in the X direction and the Y direction. The second layer portion 82 is an example of a “third portion of the insulating layer”.

The second layer portion 82 contains, for example, the same insulating material as the first layer portion 81. That is, the second layer portion 82 includes, for example, a film containing silicon and nitrogen (for example, SiN), a film containing silicon, carbon, and nitrogen (for example, SiCN), or a film containing silicon, oxygen, and nitrogen (for example, SiON). In the present embodiment, the first layer portion 81 and the second layer portion 82 are formed of the same material.

### 7.4 First Insulating Portion

The first insulating portion 91 is disposed on the side in the +Z direction with respect to the insulating layer 80. The first insulating portion 91 is provided between the bit lines BL adjacent to each other in the X direction. The first insulating portion 91 includes a first portion 91a positioned between the bit lines BL adjacent to each other in the X direction, a second portion 91b positioned between the plurality of first layer portions 81 of the insulating layer 80 adjacent to each other in the X direction, and a hollow portion (air gap) 91c provided inside the first insulating portion 91. The hollow portion (air gap) 91c is positioned between two bit lines BL adjacent to each other in the X direction.

The second portion 91b of the first insulating portion 91 is in contact with the second layer portion 82 of the insulating layer 80 in the Z direction. The first insulating portion 91 includes, for example, an insulating material containing oxygen. This insulating material is, for example, a film containing silicon and oxygen (for example, SiO₂). The first insulating portion 91 is formed of a material different from that of the insulating layer 80.

### 7.5 Via

The via V1 is an electrical connection portion that electrically connects the wiring 71 and the bit line BL. The via V1 is a self-aligned via. The via V1 is disposed between the wiring 71 and the bit line BL in the Z direction. The via V1 extends in the Z direction. The via V1 extends toward the insulating layer 80 from a side opposite to the bit line BL with respect to the insulating layer 80. The via V1 is an example of a “conductor portion”. The via V1 has, for example, a first portion 121 and a second portion 122.

The first portion 121 is a portion of the via V1 that overlaps the bit line BL when viewed from the Z direction. The first portion 121 penetrates the second layer portion 82 and the first layer portion 81 of the insulating layer 80 in the Z direction to be in contact with the bit line BL. The first portion 121 electrically connects the wiring 71 and the bit line BL. The first portion 121 is an example of a “first conductor portion”.

The second portion 122 is a portion of the via V1 that is displaced from the bit line BL when viewed from the Z direction. The second portion 122 is aligned with the first portion 121 in the X direction. The second portion 122 penetrates the second layer portion 82 of the insulating layer 80 in the Z direction to be in contact with the first insulating portion 91. An end 122e of the second portion 122 on the side in the +Z direction is positioned, for example, at a boundary B1 between the second layer portion 82 of the insulating layer 80 and the first insulating portion 91. A step 123 in the Z direction is formed between the first portion 121 and the second portion 122. The second portion 122 is an example of a “second conductor portion”.

### 7.6 Second Insulating Portion

The second insulating portion 92 is disposed on the side in the −Z direction with respect to the insulating layer 80. The second insulating portion 92 extends in the X direction and the Y direction along the second layer portion 82 of the insulating layer 80. The second insulating portion 92 contains, for example, an insulating material containing oxygen. This insulating material is, for example, a film containing silicon and oxygen (for example, SiO₂).

### A8. Manufacturing Method

### 8.1 Manufacturing Method of Semiconductor Storage Device

Next, a manufacturing method of the semiconductor storage device 1 will be described.

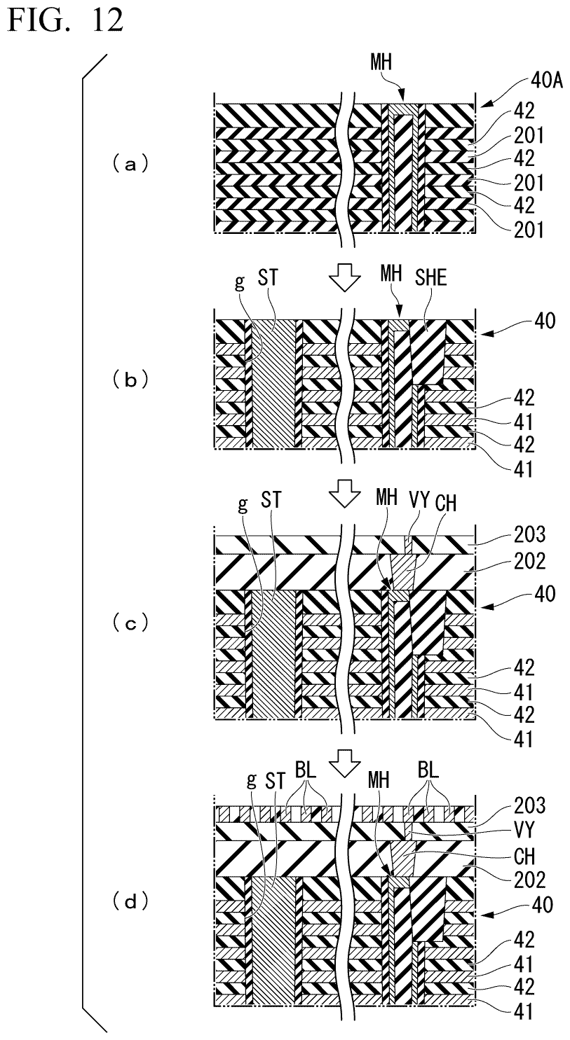

FIG. 12 is a cross-sectional view for explaining a manufacturing method of the semiconductor storage device 1. In the following, processes related to formation of the dividing portion SHE, the contact CH, the contact VY, and the bit line BL will be described. Details of other manufacturing processes are described in, for example, Japanese Unexamined Patent Application, First Publication No. 2022-41054. This literature is incorporated in the present application by reference in its entirety.

First, an insulating layer 201 and the insulating layer 42 are alternately stacked to form a multi-layered body 40A as shown in PART (a) of FIG. 12. The insulating layer 201 is a sacrificial layer that is replaced with the conductive layer 41 in a replacement process to be described later. The insulating layer 201 is formed of, for example, a film containing silicon and nitrogen. Next, a hole for providing the memory pillar MH is formed in the multi-layered body 40A, and the memory pillar MH is formed inside the hole.

Next, the dividing portion ST and the dividing portion SHE are formed as shown in PART (b) of FIG. 12. For example, a groove g for providing the dividing portion ST is formed in the multi-layered body 40A. Next, a replacement process is performed. That is, the insulating layer 201 is removed through the groove g by wet etching. Next, a material of the conductive layer 41 is supplied into a space from which the insulating layer 201 has been removed to form the conductive layer 41. Next, the dividing portion ST is formed inside the groove g. Next, a groove for providing the dividing portion SHE is formed in the multi-layered body 40A, and the dividing portion SHE is formed inside the groove.

Next, the contact CH and the contact VY are formed as shown in PART (c) of FIG. 12. For example, the insulating layer 202 is stacked on the multi-layered body 40. Next, a hole for providing the contact CH is formed in the insulating layer 202, and the contact CH is formed inside the hole. Next, an insulating layer 203 is stacked on the insulating layer 202 and the contact CH. Next, a hole for providing the contact VY is formed in the insulating layer 203, and the contact VY is formed inside the hole.

Next, the bit line BL is formed above the contact VY as shown in PART (d) of FIG. 12. Thereafter, the wiring portion 70 is formed, and thereby the second chip 3 is completed. Then, a direction of the second chip 3 is inverted vertically, and the first chip 2 and the second chip 3 are adhered together, thereby forming the semiconductor storage device 1.

### 8.2 Manufacturing Method of Portion Related to Bit Line

Next, a manufacturing method of a portion related to the bit line BL will be described.

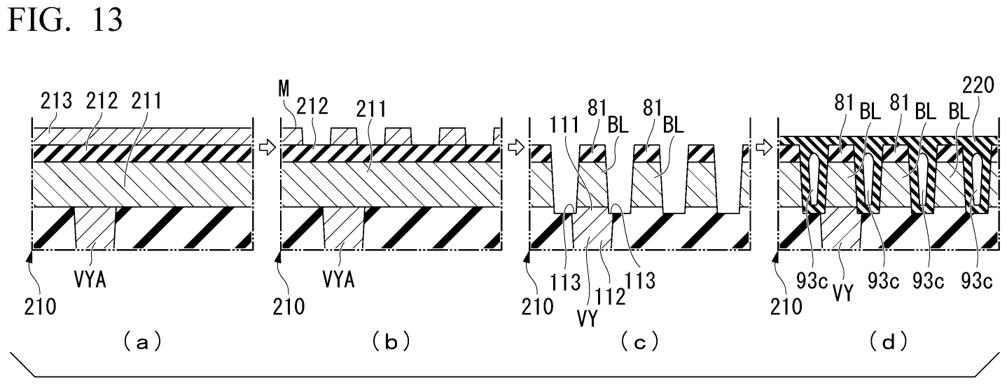

FIG. 13 is a cross-sectional view for explaining a manufacturing method around the bit line BL.

First, the multi-layered body 40, the memory pillar MH, and the contact CH, and a structure 210 including a conductive portion VYA are formed as shown in PART (a) of FIG. 13. The conductive portion VYA is a conductor portion in which the contact VY is formed by processing to be described later.

Next, a metal layer 211 is formed on the structure 210 by chemical vapor deposition (CVD). The metal layer 211 has a plate shape extending in the X direction and the Y direction. The metal layer 211 is a metal layer in which the bit line BL is formed in a later process. Next, an insulating layer 212 is formed on the metal layer 211. The insulating layer 212 extends in the X direction and the Y direction. The insulating layer 212 is an insulating film in which the plurality of first layer portions 81 of the insulating layer 80 are formed in a later process. Next, a material such as, for example, amorphous silicon is formed on the insulating layer 212 to form an insulating layer 213 which serves as a basis for a hard mask.

Next, as shown in PART (b) of FIG. 13, a hard mask M corresponding to disposition of the bit lines BL is formed from the insulating layer 213 by subjecting the insulating layer 213 to predetermined processing.

Next, as shown in PART (c) of FIG. 13, reactive ion etching is performed using the hard mask M, and thereby an unnecessary portion of the metal layer 211 and an unnecessary portion of the insulating layer 212 are removed. That is, the metal layer 211 is divided in the X direction by the reactive ion etching, and thereby the plurality of bit lines BL are formed from the metal layer 211. Also, the insulating layer 212, together with the metal layer 211, is divided in the X direction by the reactive ion etching, and thereby the plurality of first layer portions 81 of the insulating layer 80 are formed from the insulating layer 212. Also, corners of the conductive portion VYA are removed by the reactive ion etching, and thereby the contact VY is formed from the conductive portion VYA.

Next, as shown in PART (d) of FIG. 13, an insulating material is supplied between the plurality of bit lines BL and the plurality of first layer portions 81, and thereby the insulating portion 220 is formed. The insulating portion 220 has a hollow portion 93c between the bit lines BL adjacent to each other.

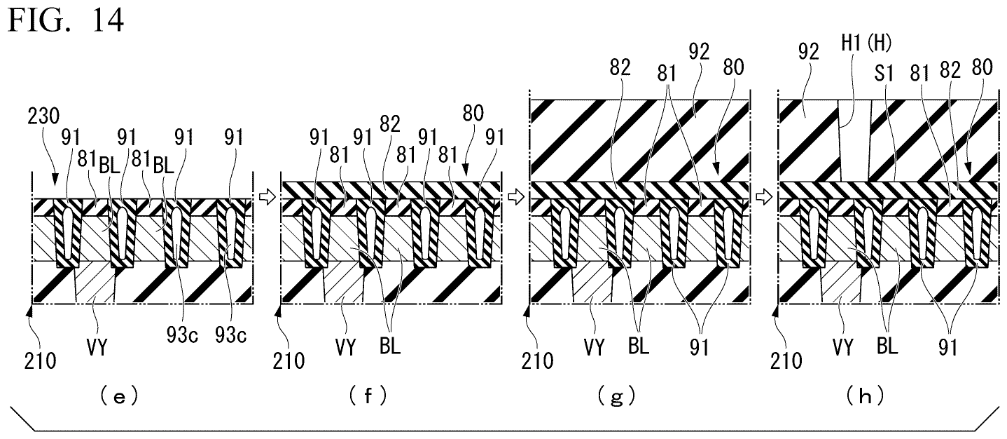

Next, as shown in PART (e) of FIG. 14, an upper end part of the insulating portion 220 is removed by a planarization treatment (chemical mechanical polishing (CMP)), and thereby the plurality of first insulating portions 91 are formed from the insulating portion 220. Therefore, an upper surface of the first insulating portion 91 is positioned on the same plane as upper surfaces of the plurality of first layer portions 81. Therefore, a structure 230 including the plurality of bit lines BL, the plurality of first layer portions 81, and the first insulating portion 91 is formed.

Next, as shown in PART (f) of FIG. 14, the second layer portion 82 is formed to cover the upper surfaces of the plurality of first layer portions 81 and the upper surface of the first insulating portion 91. Therefore, the insulating layer 80 is formed by the plurality of first layer portions 81 and the second layer portion 82.

Next, the second insulating portion 92 is formed on the insulating layer 80 as shown in PART (g) of FIG. 14. The second insulating portion 92 is formed using, for example, tetraethyl orthosilicate (TEOS, Si(OC₂H₅)₄).

Next, as shown in PART (h) of FIG. 14, a mask (not shown in the drawings) is provided, and a hole H for providing the via V1 is formed in the second insulating portion 92. The hole H is formed by, for example, reactive ion etching. The etching for forming the hole H is first performed under a first condition. The first condition is an etching condition under which the second insulating portion 92 is etched while the insulating layer 80 is difficult to etch compared to the second insulating portion 92. Therefore, first, the hole H1 that penetrates the second insulating portion 92 in the Z direction and reaches a surface S2 of the insulating layer 80 is formed.

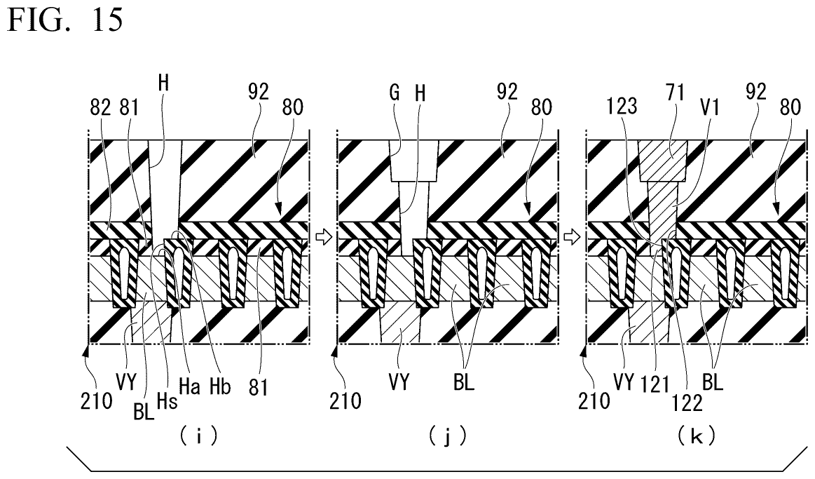

Next, as shown in PART (i) of FIG. 15, the etching for forming the hole H is performed by switching the etching condition from the first condition to a second condition. The second condition is an etching condition under which the insulating layer 80 is etched while the first insulating portion 91 is difficult to etch compared to the insulating layer 80.

Therefore, the hole H including a first portion Ha and a second portion Hb is formed. The first portion Ha is a portion of the hole H that overlaps the bit line BL when viewed from the Z direction. The first portion Ha penetrates the second layer portion 82 and the first layer portion 81 of the insulating layer 80 in the Z direction and reaches the surface of the bit line BL. The second portion Hb is a portion of the hole H that is displaced from the bit line BL when viewed from the Z direction. The second portion Hb penetrates the second layer portion 82 of the insulating layer 80 in the Z direction and remains at the upper surface of the first insulating portion 91. A step Hs in the Z direction is present between the first portion Ha and the second portion Hb.

Next, as shown in PART (j) of FIG. 15, a mask (not shown in the drawings) is provided, and a groove G for forming the wiring 71 is formed on an upper surface of the second insulating portion 92. The groove G is formed by, for example, reactive ion etching.

Next, as shown in PART (k) of FIG. 15, a conductive material is supplied into the groove G and the hole H, and thereby the wiring 71 and the via V1 are formed. At this time, the first portion 121 of the via V1 is formed in the first portion Ha of the hole H, and the second portion 122 of the via V1 is formed in the second portion Hb of the hole H.

### A9. Advantages

### 9.1 Advantages of Disposition Structure of Five in Series

First, advantages of a disposition structure of five in series will be described.

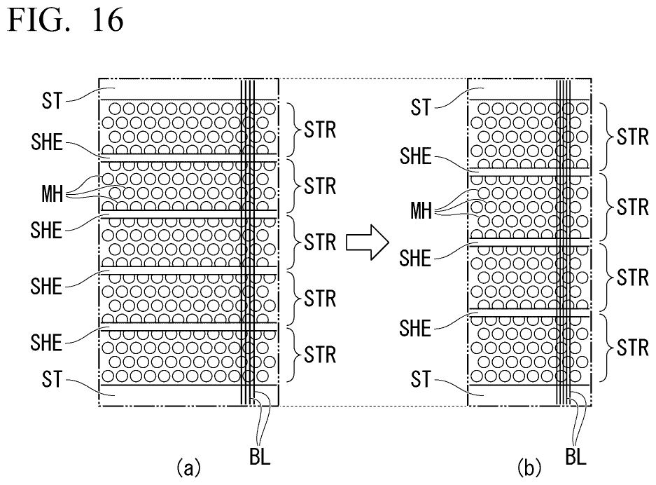

FIG. 16 is a view for explaining advantages of the configuration of five in series. PART (a) of FIG. 16 shows a disposition structure of four in series which is a comparative example. The disposition structure of four in series is a disposition structure in which four memory pillars MH are aligned in the Y direction between two adjacent dividing portions DV (that is, the dividing portion ST or the dividing portion SHE). On the other hand, PART (b) of FIG. 16 shows the disposition structure of five in series according to the present embodiment. The disposition structures of PART (a) and PART (b) in FIG. 16 are the same as each other in distance between the two dividing portions ST and the disposition structure of the plurality of memory pillars MH.

Here, each block BLK is a storage unit defined between two dividing portions ST adjacent to each other. A block size (capacity of each block BLK) is determined by multiplying four elements: the number of strings STR, the number of multi-layers of the word line WL, a multiplexing level (TLC, QLC, or the like), and a page size.

In order to increase a degree of integration of the semiconductor storage device 1, it is effective to increase the number of multi-layers of the word line WL and the number of the memory pillars MH (the number of MH in series) aligned in the Y direction between the two dividing portions ST adjacent to each other. On the other hand, if the number of multi-layers of the word line WL and the number of MH in series are increased, the block size becomes larger. If the block size becomes larger, it takes time for an erase operation, making it difficult to achieve a higher speed in the semiconductor storage device 1. Also, if the block size becomes larger, there is a likelihood that there may be a shortage of a region required for over-provisioning (OP region) or an increase in write amplification factor (WAF).

Also, as the number of multi-layers of the word line WL increases, a parasitic capacitance of the word lines increases, and a time required to drive and charge the word lines increases. Therefore, at least one of write performance and read performance may decrease. As the number of multi-layers of the word line WL increases, a size of the semiconductor storage device 1 tends to increase in the X direction, and this may make it difficult to encapsulate the semiconductor storage device 1 in a package component.

Therefore, in the present embodiment, the disposition structure of five in series is provided. According to the disposition structure of five in series, the number of strings STR included in one block BLK can be reduced compared to that of the disposition structure of four in series. Therefore, the block size can be made smaller in the disposition structure of five in series than in the disposition structure of four in series. If the block size can be reduced, it is possible to achieve a higher speed in the semiconductor storage device 1 due to reduction in time required for the erase operation. Therefore, an improvement in electrical characteristics of the semiconductor storage device 1 can be achieved. Also, if the block size can be reduced, at least one of the shortage of the OP region and the increase in the WAF can be suppressed. Also from this perspective, an improvement in electrical characteristics of the semiconductor storage device 1 can be achieved.

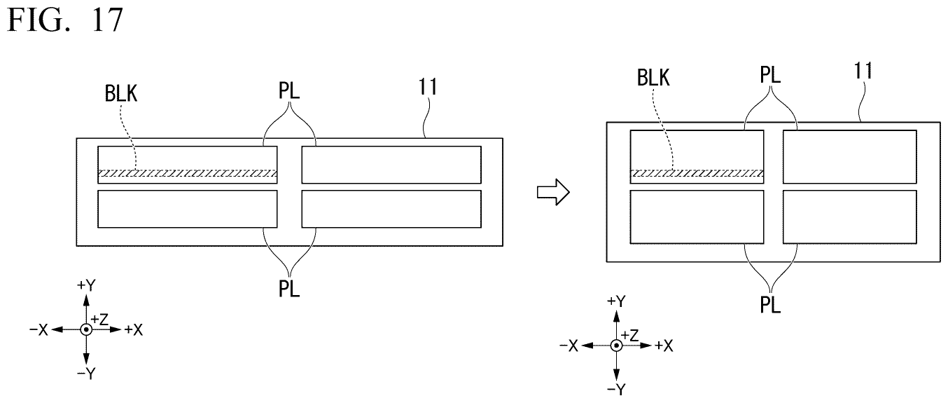

FIG. 17 is another view for explaining advantages of the configuration of five in series. PART (a) of FIG. 17 shows a plane PL having the disposition structure of four in series which is a comparative example. PART (b) of FIG. 17 shows a plane PL having the disposition structure of five in series according to the present embodiment. The plane PL is a unit of a physical structure included in the memory cell array 11 as a configuration including the plurality of blocks BLK. In the disposition structures of PART (a) and PART (b) in FIG. 17, the number of the memory cell transistors MT included in the plane PL is the same.

In the disposition structure of five in series according to the present embodiment, if the number of the memory cell transistors MT included in each string STR is set to be the same as the number of the memory cell transistors MT included in each string STR in the configuration of four in series, a length of the plane PL in the X-direction (a length of the word line WL in the X-direction) is reduced to four-fifths of that in the disposition structure of four in series. If the length of the word line WL in the X direction can be reduced, a parasitic capacitance of the word line WL can be reduced. Therefore, in a case in which the charging or propagation delay of the word line WL limits at least one of the write performance and the read performance of the semiconductor storage device 1, it is possible to improve at least one of the write performance and read performance of the semiconductor storage device 1. Also, if the length of the plane PL in the X direction can be reduced, encapsulation of the semiconductor storage device 1 into a package component may be easily performed.

In the present embodiment, the width W3 in the X direction of the first end 110a of the contact VY is the same as the width W2 in the X direction of the second end 101b of the bit line BL2. According to such a configuration, in a case in which misalignment occurs between the contact VY and the bit line BL, even if the plurality of bit lines BL are densely aligned in the X direction, it becomes easier to secure a distance between the contact VY and the bit line BL. Therefore, in a dense disposition structure of the bit lines BL corresponding to the disposition structure of five in series, a withstand voltage can be enhanced, and thus an improvement in electrical characteristics of the semiconductor storage device 1 can be achieved.

In the present embodiment, the via V1 includes the first portion 121 that penetrates the second layer portion 82 and the first layer portion 81 of the insulating layer 80 in the Z direction to be in contact with the bit line BL, and the second portion 122 that penetrates the second layer portion 82 of the insulating layer 80 in the Z direction to be in contact with the first insulating portion 91 and has the step 123 between itself and the first portion 121. According to such a configuration, in a case in which misalignment occurs between the via V1 and the bit line BL, even if the plurality of bit lines BL are densely aligned in the X direction, it becomes easier to secure a distance between the via V1 and the bit line BL. Therefore, in the dense disposition structure of the bit lines BL corresponding to the disposition structure of five in series, a withstand voltage can be enhanced, and thus an improvement in electrical characteristics of the semiconductor storage device 1 can be achieved.

In the present embodiment, the first insulating portion 91 disposed between the bit lines BL includes the hollow portion (air gap) 91c positioned between the plurality of bit lines BL in the X direction. According to such a configuration, in the dense disposition structure of the bit lines BL corresponding to the disposition structure of five in series, a reduction in parasitic capacitance generated in the bit lines BL can be achieved, and thus an improvement in electrical characteristics of the semiconductor storage device 1 can be achieved.

### A10. Modified Example

Next, some modified examples of the first embodiment will be described. Note that, configurations of each modified example other than those described below are the same as the configurations of the first embodiment.

### 10.1 First Modified Example

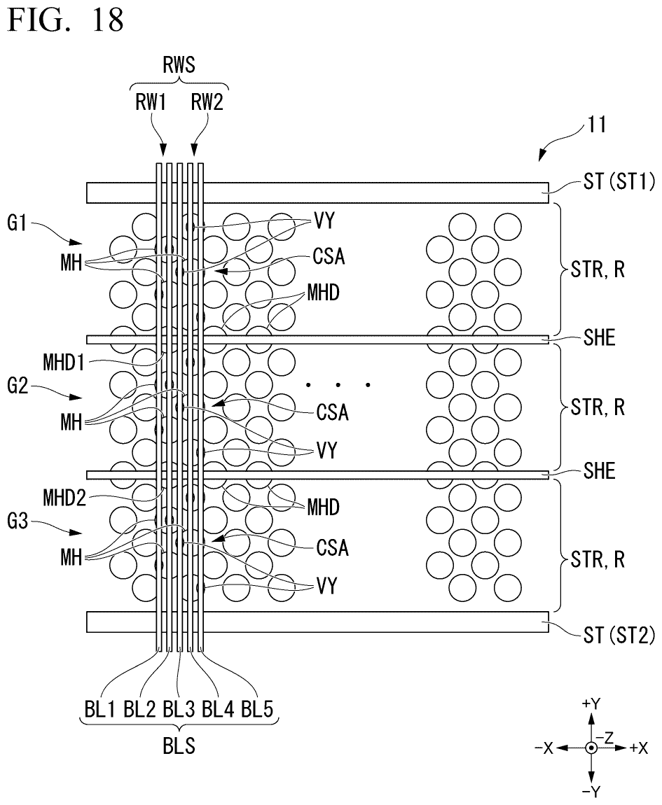

FIG. 18 is a cross-sectional view showing a part of the semiconductor storage device 1 of a first modified example. In the present modified example, 17 memory pillars MH are aligned in the Y direction in a region between two adjacent dividing portions ST (dividing portions ST1 and ST2). The 17 memory pillars MH are disposed alternately in the first row RW1 and the second row RW2. The 17 memory pillars MH include five memory pillars MH in the first group G1, five memory pillars MH in the second group G2, five memory pillars MH in the third group G3, and two dummy memory pillars MHD (dummy memory pillars MHD1 and MHD2). In the present modified example, the 17 memory pillars MH including the two dummy memory pillars MHD are disposed at regular intervals in the Y direction.

The dummy memory pillar MHD is a columnar body that has the same configuration as the memory pillar MH, but is not electrically connected to the bit line BL and is not used to store data. The dummy memory pillar MHD1 is disposed between the five memory pillars MH of the first group G1 and the five memory pillars MH of the second group G2 in the Y direction. When viewed from the Z direction, one dividing portion SHE is disposed at a position overlapping the dummy memory pillar MHD1. Similarly, the dummy memory pillar MHD2 is disposed between the five memory pillars MH of the second group G2 and the five memory pillars MH of the third group G3 in the Y direction. When viewed from the Z direction, one dividing portion SHE is disposed at a position overlapping the dummy memory pillar MHD2.

### 10.2 Second Modified Example

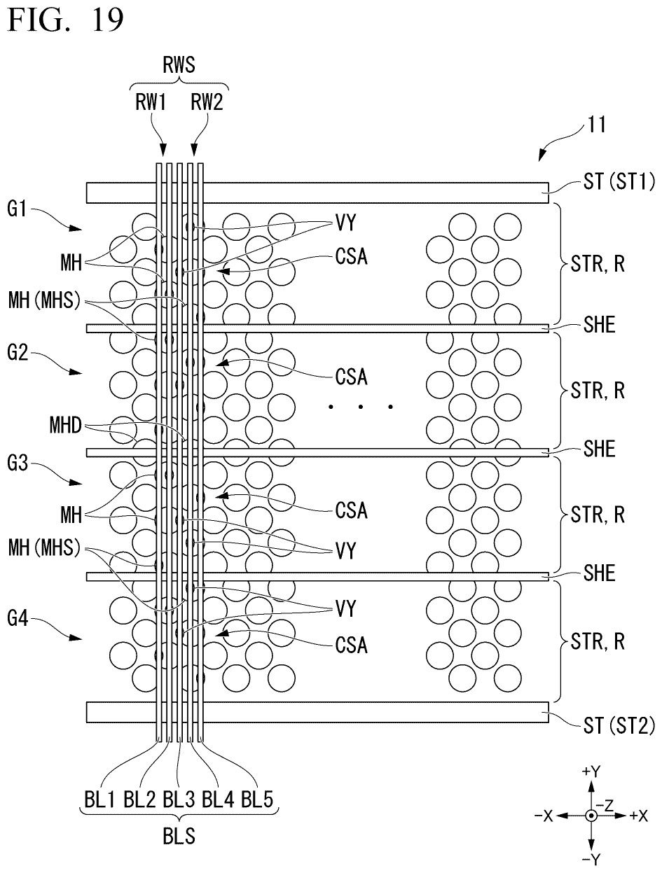

FIG. 19 is a cross-sectional view showing a part of the semiconductor storage device 1 of a second modified example. In the present modified example, 21 memory pillars MH are aligned in the Y direction in a region between two adjacent dividing portions ST (dividing portions ST1 and ST2). The 21 memory pillars MH are disposed alternately in the first row RW1 and the second row RW2. The 21 memory pillars MH include five memory pillars MH in the first group G1, five memory pillars MH in the second group G2, five memory pillars MH in the third group G3, five memory pillars MH in the fourth group G4, and one dummy memory pillar MHD. Each of the first group G1 to the fourth group G4 includes one or two memory pillars MHS. The memory pillar MHS is a memory pillar MH that partially overlaps the dividing portion SHE when viewed from the Z direction, but is connected to the bit line BL via the contact VY to function electrically. In the present modified example, the 21 memory pillars MH including one dummy memory pillar MHD and the plurality of memory pillars MHS are disposed at regular intervals in the Y direction.

### Second Embodiment

Next, a semiconductor storage device 1 according to a second embodiment will be described. The semiconductor storage device 1 according to the second embodiment differs from the first embodiment in that only three memory pillars MH are disposed in the Y direction in a region R between two dividing portions DV adjacent to each other. Note that, configurations other than those described below are the same as the configurations of the first embodiment.

### B1. Configuration of Semiconductor Storage Device

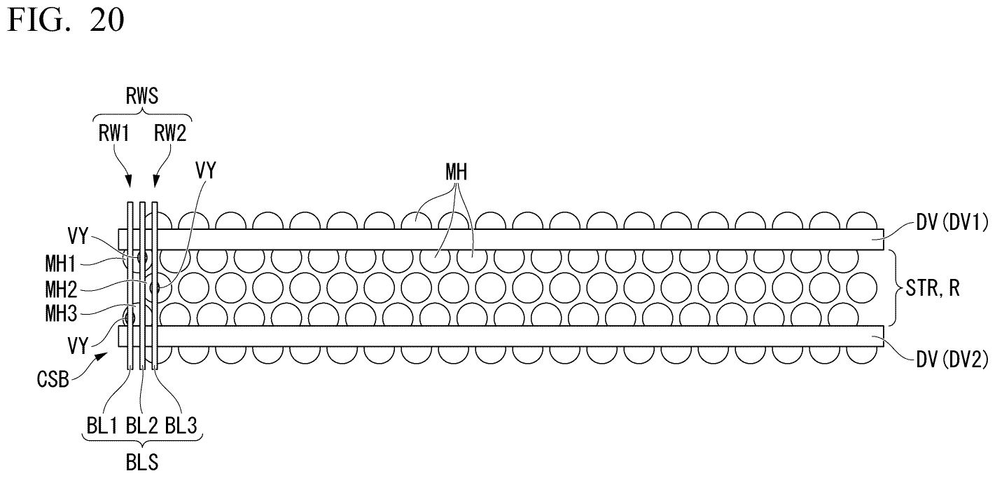

FIG. 20 shows a structure related to two adjacent dividing portions DV (a first dividing portion DV1 and a second dividing portion DV2) among the plurality of dividing portions DV. In the example shown in FIG. 20, the first dividing portion DV1 and the second dividing portion DV2 are formed by a dividing portion SHE. Note that, one or both of the first dividing portion DV1 and the second dividing portion DV2 may be formed by the dividing portion ST instead of the dividing portion SHE. A region R corresponding to one string STR is defined between the first dividing portion DV1 and the second dividing portion DV2.

In the present embodiment, a plurality of memory pillars MH are disposed in the region R between the two adjacent dividing portions DV in a disposition structure in which three memory pillars MH are aligned in the Y direction (hereinafter, referred to as a “disposition structure of three in series”).

In the present embodiment, a connection structure between a bit line set BLS including three bit lines BL (bit lines BL1 to BL3) adjacent to each other in the X direction and three memory pillars MH (memory pillars MH1 to MH3) corresponding to the three bit lines BL forms one structural unit. Then, the above-described connection structure is repeatedly present in the X direction for every three bit lines BL. Also, the above-described connection structure is repeatedly present for each region R in the Y direction. Therefore, in the following, one connection structure will be described in detail.

### 1.1 Disposition of Memory Pillars

The three memory pillars MH include a first memory pillar MH1, a second memory pillar MH2, and a third memory pillar MH3. The first memory pillar MH1, the second memory pillar MH2, and the third memory pillar MH3 are aligned in that order in the Y direction.

In the present embodiment, the first memory pillar MH1, the second memory pillar MH2, and the third memory pillar MH3 are disposed separately in a first row RW1 and a second row RW2 included in one row set RWS. The first memory pillar MH1, the second memory pillar MH2, and the third memory pillar MH3 are alternately disposed in the first row RW1 and the second row RW2. For example, the first memory pillar MH1 and the third memory pillar MH3 are disposed in the first row RW1. The second memory pillar MH2 is disposed in the second row RW2. In the present embodiment, the first memory pillar MH1, the second memory pillar MH2, and the third memory pillar MH3 partially overlap each other when viewed from the Y direction.

### 1.2 Disposition of Bit Lines

The three bit lines BL include a first bit line BL1, a second bit line BL2, and a third bit line BL3. The first bit line BL1, the second bit line BL2, and the third bit line BL3 are disposed in that order in the X direction. In the present embodiment, a pitch between centers of the plurality of bit lines BL in the X direction is, for example, 40 nm or more.

### 1.3 Connection Structure

The first memory pillar MH1 overlaps the second bit line BL2 when viewed from the Z direction. The first memory pillar MH1 is electrically connected to the second bit line BL2 via a contact VY. The second memory pillar MH2 overlaps the third bit line BL3 when viewed from the Z direction. The second memory pillar MH2 is electrically connected to the third bit line BL3 via the contact VY. The third memory pillar MH3 overlaps the first bit line BL1 when viewed from the Z direction. The third memory pillar MH3 is electrically connected to the first bit line BL1 via the contact VY.

As described above, each of the three memory pillars MH (MH1 to MH3) is electrically connected to different bit lines BL within the three bit lines BL (BL1 to BL3) included in one bit line set BLS. In the following, the above-described connection structure between the three memory pillars MH and the three bit lines BL will be referred to as a connection structure CSB. In the present embodiment, the connection structure CSB is provided in each of the plurality of regions R.

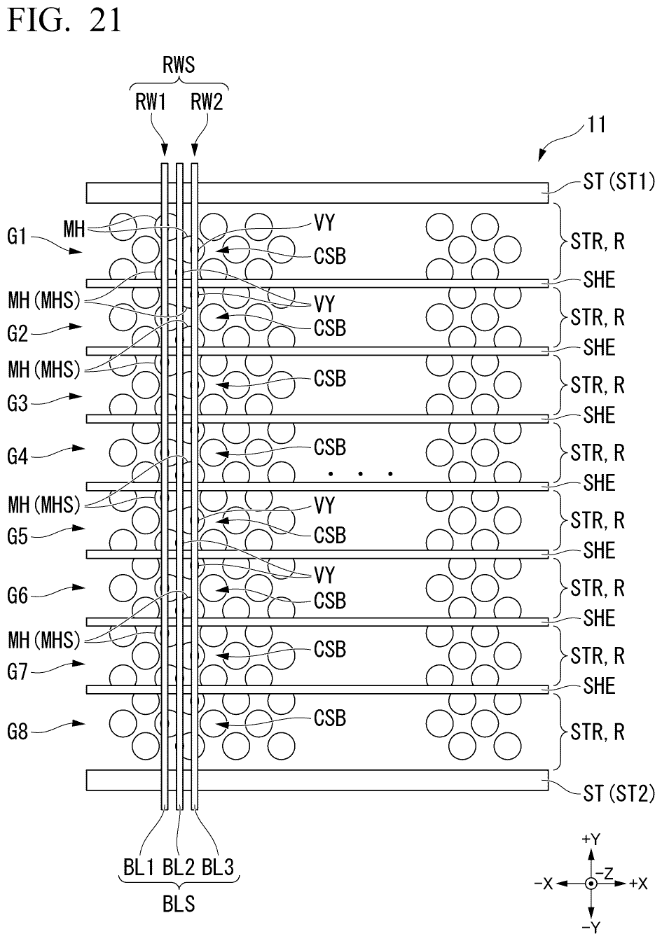

FIG. 21 is a cross-sectional view showing a part of the semiconductor storage device 1 according to the second embodiment. In the present embodiment, 24 memory pillars MH are aligned in the Y direction in a region between two adjacent dividing portions ST (dividing portions ST1 and ST2). The 24 memory pillars MH are disposed alternately in the first row RW1 and the second row RW2. The 24 memory pillars MH include memory pillars MH divided into groups of three each and disposed from the first group G1 to the eighth group G8.

In the present embodiment, each of the first group G1 to the eighth group G8 includes the memory pillar MHS that is closest to the adjacent region R. As described above, a part of the memory pillar MHS overlaps the dividing portion SHE when viewed from the Z direction. In the present embodiment, the memory pillar MHS overlapping the dividing portion SHE when viewed from the Z direction is a memory pillar MH that is connected to the bit line BL via the contact VY to function electrically.

As described above, in the region R between the first dividing portion DV1 and the second dividing portion DV2 disposed adjacent to the first dividing portion DV1 in the Y direction, the plurality of memory pillars MH include only two or less memory pillars MH (for example, two memory pillars MH1 and MH3) as the memory pillar MH disposed in the first row RW1 extending in the Y direction, and include one memory pillar MH2 as the memory pillar MH disposed in the second row RW2 extending in the Y direction and adjacent to the first row RW1 in the X direction. The two or less memory pillars MH (for example, the two memory pillars MH1 and MH3) and the one memory pillar MH2 are disposed alternately in the Y direction. Then, the two or less memory pillars MH (for example, the two memory pillars MH1 and MH3) and the one memory pillar MH2 are electrically connected to different bit lines BL among the plurality of bit lines BL.

### B2. Advantages

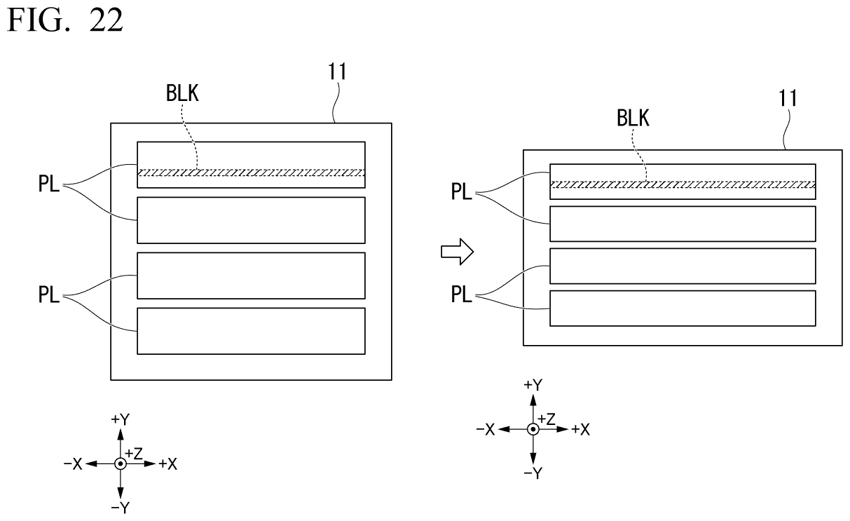

FIG. 22 is another view for explaining advantages of the configuration of three in series. PART (a) of FIG. 22 shows a plane PL having a disposition structure of four in series which is a comparative example. PART (b) of FIG. 22 shows a plane PL having a disposition structure of three in series according to the present embodiment. The plane PL is a unit of a physical structure included in a memory cell array 11 as a configuration including a plurality of blocks BLK. In the disposition structures of PART (a) and PART (b) in FIG. 22, the number of the memory cell transistors MT included in the plane PL is the same.

At least one of write performance and read performance of the semiconductor storage device 1 may be limited by charging or propagation delay of the bit lines BL instead of charging or propagation delay of the word lines WL. In the disposition structure of three in series according to the present embodiment, if the number of the memory cell transistors MT included in each string unit SU is made the same as the number of the memory cell transistors MT included in each string unit SU of the disposition structure of four in series, a length in the Y-direction of the plane PL (a length in the Y-direction of the bit line BL) is reduced to three-quarters of that in the disposition structure of four in series. If the length of the bit line BL in the X direction can be reduced, a parasitic capacitance of the bit line BL can be reduced. Therefore, in a case in which the charging or propagation delay of the bit line BL limits at least one of the write performance and the read performance of the semiconductor storage device 1, it is possible to improve at least one of the write performance and the read performance of the semiconductor storage device 1. Therefore, an improvement in electrical characteristics of the semiconductor storage device 1 can be achieved. Also, if the length of the plane PL in the Y direction can be reduced, encapsulation of the semiconductor storage device 1 into a package component may be easily performed.

### B3. Modified Examples

Next, some modified examples of the second embodiment will be described. Note that, configurations of each modified example other than those described below are the same as the configurations of the second embodiment.

### 3.1 First Modified Example

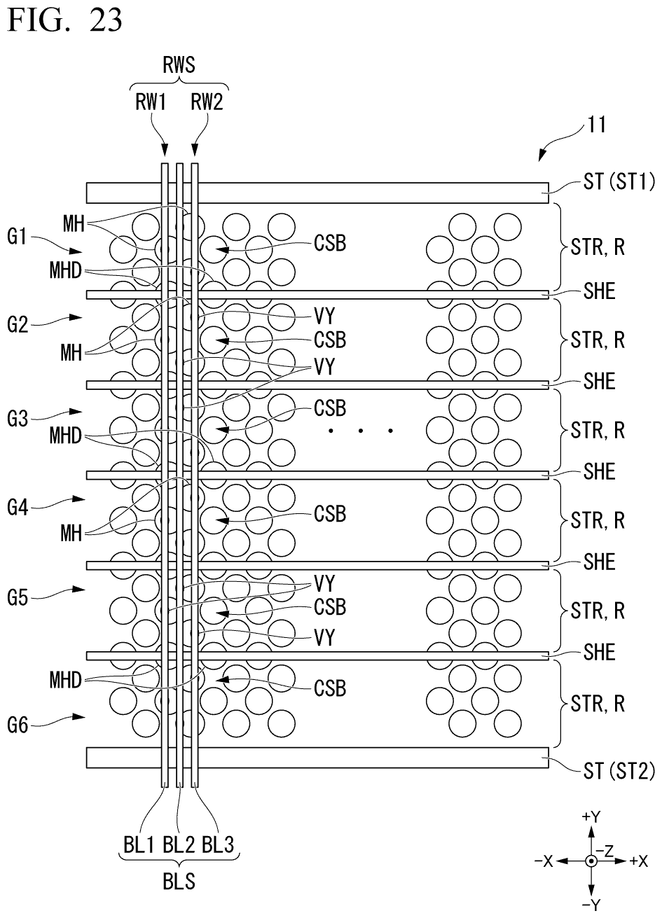

FIG. 23 is a cross-sectional view showing a part of the semiconductor storage device 1 of a first modified example. In the present modified example, 23 memory pillars MH are aligned in the Y direction in a region between two adjacent dividing portions ST (dividing portions ST1 and ST2). The 23 memory pillars MH are disposed alternately in the first row RW1 and the second row RW2. The 23 memory pillars MH include memory pillars MH that are divided into groups of three each and disposed from the first group G1 to the sixth group G6, and five dummy memory pillars MHD. In the present modified example, the 23 memory pillars MH including the five dummy memory pillars MHD are disposed at regular intervals in the Y direction.

### 10.2 Second Modified Example

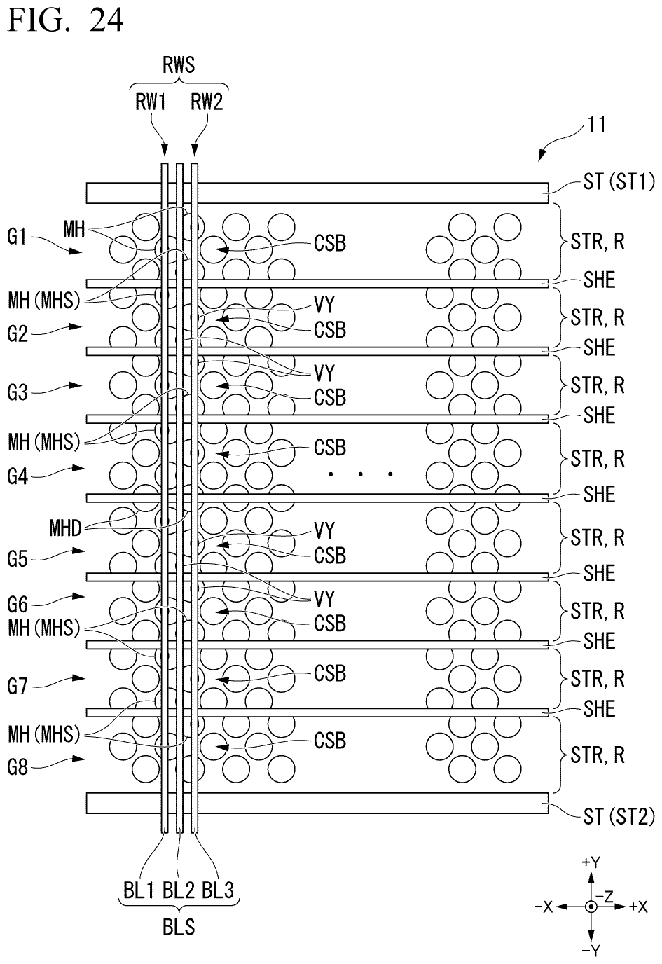

FIG. 24 is a cross-sectional view showing a part of the semiconductor storage device 1 of a second modified example. In the present modified example, 23 memory pillars MH are aligned in the Y direction in a region between two adjacent dividing portions ST (dividing portions ST1 and ST2). The 23 memory pillars MH are disposed alternately in the first row RW1 and the second row RW2. The 23 memory pillars MH include memory pillars MH that are divided into groups of three each and disposed from the first group G1 to the eighth group G8, and one dummy memory pillar MHD. The three memory pillars MH contained in each of the first group G1 to the eighth group G8 include one or two memory pillars MHS. The memory pillar MHS is a memory pillar MH that partially overlaps the dividing portion SHE when viewed from the Z direction, but is connected to the bit line BL via the contact VY to function electrically. In the present modified example, the 23 memory pillars MH including one dummy memory pillar MHD and the plurality of memory pillars MHS are disposed at regular intervals in the Y direction.

Some embodiments and modified examples have been described above. However, the embodiments and modified examples are not limited to the examples described above. For example, in the first embodiment, the number of the memory pillars MH aligned in the Y direction in the region R between two adjacent dividing portions DV is not limited to five, and may be six or more. Also, in the second embodiment, the number of the memory pillars MH aligned in the Y direction in the region R between two adjacent dividing portions DV is not limited to three, and may be two.

According to at least one of the embodiments described above, a semiconductor storage device includes a multi-layered body, a plurality of columnar bodies, a plurality of bit lines, and a plurality of dividing portions. The plurality of dividing portions are disposed separately in the third direction. The plurality of dividing portions include a first dividing portion and a second dividing portion adjacent to each other among the plurality of dividing portions. In a region between the first dividing portion and the second dividing portion, the plurality of columnar bodies include three or more columnar bodies disposed in a first row extending in the third direction, and two or more columnar bodies disposed in a second row extending in the third direction and adjacent to the first row in the second direction. The three or more columnar bodies and the two or more columnar bodies are disposed alternately in the third direction. The three or more columnar bodies and the two or more columnar bodies are electrically connected to different bit lines among the plurality of bit lines. According to such a configuration, an improvement in electrical characteristics can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a multi-layered body including a plurality of gate electrode layers and a plurality of insulating layers, the plurality of gate electrode layers and the plurality of insulating layers being alternately stacked one by one in a first direction;
a plurality of columnar bodies extending in the first direction within the multi-layered body, the plurality of columnar bodies and the plurality of gate electrode layers forming intersections, the intersections including transistors;
a plurality of bit lines on one side of the multi-layered body in the first direction, the plurality of bit lines being in a second direction intersecting the first direction, each of the plurality of bit lines extending in a third direction intersecting the first direction and the second direction; and
a plurality of dividing portions separately in the third direction, each of the plurality of dividing extending in the first direction within the multi-layered body, and the plurality of dividing dividing one or more gate electrode layers including a lowermost layer among the plurality of gate electrode layers in the third direction when the one side is defined as a downward side, wherein
the plurality of dividing portions include a first dividing portion and a second dividing portion adjacent to each other among the plurality of dividing portions,
in a region between the first dividing portion and the second dividing portion, the plurality of columnar bodies include three or more columnar bodies in a first row extending in the third direction, the plurality of columnar bodies include two or more columnar bodies in a second row extending in the third direction and adjacent to the first row in the second direction,
the three or more columnar bodies and the two or more columnar bodies are alternately in the third direction, and
the three or more columnar bodies and the two or more columnar bodies are electrically connected to different bit lines among the plurality of bit lines.

2. The semiconductor storage device according to claim 1, wherein
the plurality of bit lines include a first bit line,
the first bit line has a first end and a second end,
the first end faces a side opposite to the multi-layered body,
the second end faces the multi-layered body, and
a width of the first end in the second direction is smaller than a width of the second end in the second direction.

3. The semiconductor storage device according to claim 2, further comprising
a contact between the first bit line and a first columnar body, the first columnar body in the plurality of columnar bodies, wherein
the contact has an end in contact with the second end of the first bit line, and
a width of the end of the contact in the second direction is the same as a width of the second end of the first bit line in the second direction.

4. The semiconductor storage device according to claim 2, further comprising
a contact between the first bit line and a first columnar body, the first columnar body in the plurality of columnar bodies, wherein
the contact has a first portion and a second portion,
the first portion is in contact with the first bit line,
the second portion is between the first portion and the first columnar body,
the first portion has a width in the second direction which increases as the first portion comes closer to the first columnar body, and
the second portion has a width in the second direction which decreases as the second portion comes closer to the first columnar body.

5. The semiconductor storage device according to claim 1, further comprising:
an insulating layer overlapping the plurality of bit lines when viewed from the first direction;
a via penetrating the insulating layer in the first direction; and
an insulating portion between the plurality of bit lines, wherein
the plurality of bit lines include a first bit line and a second bit line adjacent to the first bit line,
the insulating layer includes a first portion, a second portion, and a third portion,
the first portion overlaps the first bit line when viewed from the first direction,
the second portion overlaps the second bit line when viewed from the first direction,
the third portion is on a side opposite to the plurality of bit lines with respect to the first portion and the second portion,
the third portion extends at least in the second direction,
the via includes a first conductor portion and a second conductor portion,
the first conductor portion penetrates the third portion and the first portion of the insulating layer in the first direction to be in contact with the first bit line,
the second conductor portion penetrates the third portion of the insulating layer in the first direction to be in contact with the insulating portion, and
the second conductor portion includes a step between the first conductor portion and the second conductor portion.

6. The semiconductor storage device according to claim 5, wherein
the insulating portion includes a hollow portion between the plurality of bit lines in the second direction.

7. A semiconductor storage device comprising:
a multi-layered body including a plurality of gate electrode layers and a plurality of insulating layers, the plurality of gate electrode layers and the plurality of insulating layers being alternately stacked one by one in a first direction;
a plurality of columnar bodies extending in the first direction within the multi-layered body, the plurality of columnar bodies and the plurality of gate electrode layers forming intersections, the intersections including transistors;
a plurality of bit lines on one side of the multi-layered body in the first direction, the plurality of bit lines being in a second direction intersecting the first direction, each of the plurality of bit lines extending in a third direction intersecting the first direction and the second direction; and
a plurality of dividing portions separately in the third direction, each of the plurality of dividing extending in the first direction within the multi-layered body, and the plurality of dividing dividing one or more gate electrode layers including a lowermost layer among the plurality of gate electrode layers in the third direction when the one side is defined as a downward side, wherein
the plurality of dividing portions include a first dividing portion and a second dividing portion adjacent to each other among the plurality of dividing portions,
in a region between the first dividing portion and the second dividing portion, the plurality of columnar bodies include only two or less columnar bodies as a columnar body in a first row extending in the third direction, the plurality of columnar bodies include only one columnar body as a columnar body in a second row extending in the third direction and adjacent to the first row in the second direction,
the two or less columnar bodies and the one columnar body are alternately in the third direction, and
the two or less columnar bodies and the one columnar body are electrically connected to different bit lines among the plurality of bit lines.
